(19) United States
(12) Patent Application Publication
(10) Pub. No.: US 2021/0195757 A1
(43) Pub. Date: Jun. 24, 2021

(54) PRODUCING METHOD OF WIRING CIRCUIT BOARD AND WIRING CIRCUIT BOARD SHEET

(71) Applicant: NITTO DENKO CORPORATION, Osaka (JP)

(72) Inventors: Takahiro MINATOYA, Osaka (JP); Takahiro TAKANO, Osaka (JP); Masataka YAMAJI, Osaka (JP)

(73) Assignee: NITTO DENKO CORPORATION, Osaka (JP)

(21) Appl. No.: 17/117,857

(22) Filed: Dec. 10, 2020

(30) Foreign Application Priority Data
Dec. 24, 2019 (JP) 2019-232710

(51) Int. Cl. H05K 3/06; G03F 7/20

(52) U.S. Cl. CPC H05K 3/064; H05K 2203/166; G03F 7/2014

(57) ABSTRACT

In a step of forming a conductive pattern, a photoresist is exposed a plurality of times while a fourth mask including a fourth light shielding mark and a fifth mask including a sixth light shielding mark are sequentially arranged in a longitudinal direction, and the photoresist is developed to form a plating resist, and the plating is carried out using this. In a step of exposing the plating resist, in the photoresist, an opposing portion of the fourth mask at the time of the first exposure is overlapped with the fifth mask at the time of the second exposure. A first conductive mark is formed by the first exposure of the photoresist through the fourth light shielding mark and by plating using the plating resist. A third conductive mark is formed by the second exposure of the photoresist through the fifth mask and by plating using the plating resist.

### CROSS REFERENCE TO RELATED APPLICATION

The present application claims priority from Japanese Patent Application No. 2019-232710 filed on Dec. 24, 2019, the contents of which are hereby incorporated by reference into this application.

### TECHNICAL FIELD

The present invention relates to a method for producing a wiring circuit board, and a wiring circuit board sheet.

### BACKGROUND ART

Conventionally, a method for producing a flexible substrate for forming a wiring pattern in an insulating layer by a pattern forming method of an additive method or a subtractive method has been known.

For example, as a method for forming the wiring pattern by the subtractive method, a method in which an exposure mask having an opening portion of an equal length of a width of both end portions is provided on a photosensitive resist layer disposed on the surface of a metal layer so as to sequentially overlap end portions of the opening portion in a longitudinal direction, and the resist layer is repeatedly exposed has been proposed (ref. for example, Patent Document 1 below).

In Patent Document 1, by development after exposure, a resist pattern having a linear shape of the same width over the longitudinal direction is formed, and then, by etching the metal layer exposed from the resist pattern, a wiring pattern having a linear shape of the same width over the longitudinal direction is formed.

### Prior Art Document

### Patent Document

[Patent Document 1] Japanese Unexamined Patent Publication No. 2005-286207

### SUMMARY OF THE INVENTION

### Problems to be Solved by the Invention

However, when the exposure mask is moved in the longitudinal direction, the end portions of the opening portion in the exposure mask may deviate in a width direction. In this case, there is a request to measure an amount of deviation and adjust the arrangement of the mask based on the measured amount.

According to the method described in Patent Document 1, even when the shape caused by the above-described deviation in the wiring pattern that is finally formed can be observed, there is a problem that the above-described deviation of the mask cannot be measured. More specifically, a portion of the resist layer facing the exposure mask includes a portion exposed once and a portion exposed twice, and these portions cannot be distinguished by observing the shape of the wiring pattern described above. Therefore, the amount of deviation of the exposure mask cannot be accurately measured. Therefore, the arrangement of the exposure mask cannot be adjusted.

Furthermore, there is also a demand to accurately measure the deviation of the wiring pattern caused by the above-described deviation of the mask.

The present invention provides a wiring circuit board which can accurately measure an amount of deviation of a mask, can correct the arrangement of the mask, and can further measure the deviation of a wiring pattern, and a method for producing a wiring circuit board.

### Solution to the Problems

The present invention (1) includes a method for producing a wiring circuit board including the steps of forming an elongated insulating layer, and forming a conductive layer elongated along the insulating layer find adjacent to the insulating layer in a thickness direction perpendicular to a longitudinal direction, wherein the conductive layer has an intermediate portion located between one end portion and the other end portion in the longitudinal direction, in the step of forming the conductive layer, an elongated photoresist is placed along the insulating layer on one side in the thickness direction of the insulating layer, the photoresist is exposed a plurality of times while a mask is sequentially arranged in the longitudinal direction, the photoresist is developed after exposure, a resist corresponding to the conductive layer is formed, and plating or etching is carried out using the resist, the mask has at least a pattern corresponding to the intermediate portion of the conductive layer, in the step of exposing the photoresist, in the photoresist, a portion facing the longitudinal other end portion of the mask at the time of the n-th time (n is a natural number) exposure is overlapped with a portion facing the longitudinal one end portion of the mask at the time of the [n+1]th time exposure, the longitudinal other end portion of the n-th time mask includes the pattern and a first mark, the longitudinal one end portion of the [n+1]th time mask includes the pattern and a second mark, and in the step of forming the conductive layer, one conductive mark portion is formed by the n-th time exposure of the photoresist through the first mark, formation of the resist by development of the photoresist after exposure, and plating or etching using the resist and another conductive mark portion adjacent to the one conductive mark portion when projected in the longitudinal direction is formed by the [n+1]th time exposure of the photoresist through the second mark, formation of the resist by development of the photoresist after exposure, and plating or etching using the resist.

In this method, a distance between the one conductive mark portion and the other conductive mark portion is measured, and tins distance is evaluated based on a distance between the first mark and the second mark in a projected surface when projected in the longitudinal direction in the mask, so that an amount of deviation between the longitudinal other end portion of the n-th time mask and the longitudinal one end portion of the [n+1]th time mask can be measured.

Therefore, it is possible to adjust the arrangement of the mask when the same step is carried out thereafter.

Furthermore, since it is possible to measure the amount of deviation of the mask described above, an amount of deviation between the longitudinal other end portion of the intermediate portion corresponding to the pattern of the n-th time mask and the longitudinal one end portion of the intermediate portion corresponding to the pattern of the [n+1]th time mask can be accurately measured. Therefore, the defectiveness of the conductive layer can be accurately determined.

The present invention (2) includes the method for producing a wiring circuit board described in (1), wherein one of the one conductive mark portion and the other conductive mark portion includes one portion and the other portion which are arranged to be opposed to each other at a distance in a direction perpendicular to the longitudinal direction and the thickness direction, and the other includes a middle portion which is arranged between one portion and the other portion and is separated from one portion and the other portion.

In this method, by measuring a distance between the middle portion and one portion, and a distance between the middle portion and the other portion, the amount of deviation between the longitudinal other end portion of the n-th time mask and the longitudinal one end portion of the [n+1]th time mask can be further accurately measured.

Therefore, it is possible to accurately adjust the arrangement of the mask when the same step is carried out thereafter.

Furthermore, the amount of deviation between the longitudinal other end portion of the intermediate portion corresponding to the pattern of the n-th time mask and the longitudinal one end portion of the intermediate portion corresponding to the pattern of the [n+1]th time mask can be further accurately measured. Therefore, the defectiveness of the conductive layer can be further accurately determined.

The present invention (3) includes the method for producing a wiring circuit board described in (1) or (2), wherein a plurality of measurement mark portions including the one conductive mark portion and the other conductive mark portion are arranged at intervals from each other in a direction perpendicular to the longitudinal direction and the thickness direction.

In this method, the plurality of measurement mark portions are arranged at intervals from each other in the perpendicular direction, it is possible to measure an amount of rotation when the [n+1]th time mask is rotated with respect to the n-th time mask.

The present invention (4) includes a method for producing a wiring circuit board including the steps of forming an elongated insulating layer, and forming a conductive layer elongated along the insulating layer and adjacent to the insulating layer in a thickness direction perpendicular to a longitudinal direction, wherein the insulating layer has an intermediate portion located between one end portion and the other end portion in the longitudinal direction, in the step of forming the insulating layer, an elongated photosensitive resin insulating layer is placed, the photosensitive resin insulating layer is exposed a plurality of times while a mask is sequentially arranged in the longitudinal direction, and the photosensitive resin insulating layer is developed after exposure, the mask has at least a pattern corresponding to the intermediate portion of the insulating layer, in the step of exposing the photosensitive resin insulating layer, in the photosensitive resin insulating layer, a portion facing the longitudinal other end portion of the mask at the time of the n-th time (n is a natural number) exposure is overlapped with a portion facing the longitudinal one end portion of the mask at the time of the [n+1]th time exposure, the longitudinal other end portion of the n-th time mask includes the pattern and a third mark, the longitudinal one end portion of the [n+1]th time mask includes the pattern and a fourth mark, and in the step of forming the insulating layer, one insulating mark portion is formed by the n-th time exposure of the photosensitive resin insulating layer through the third mark and development of the photosensitive resin insulating laser after exposure and another insulating mark portion adjacent to the one insulating mark portion when projected in the longitudinal direction is formed by the [n+1]th time exposure of the photosensitive resin insulating layer through the fourth mark and development of the photosensitive resin insulating layer after exposure.

In this method, a distance between the first insulating mark and the second insulating mark is measured, and this distance is evaluated based on a distance between the third mark and the fourth mark in a projected surface when projected in the longitudinal direction in the mask, so that an amount of deviation between the longitudinal other end portion of the n-th time mask and the longitudinal one end portion of the [n+1]th time mask can be measured.

Therefore, it is possible to adjust the arrangement of the mask when the same step is carried out thereafter.

Furthermore, live amount of deviation between the longitudinal other end portion of the intermediate portion corresponding to the pattern of the n-th time mask and the longitudinal one end portion of the intermediate portion corresponding to the pattern of the [n+1]th time mask can be accurately measured. Therefore, the defectiveness of the insulating layer can be accurately determined.

The present invention (5) includes a wiring circuit board sheet including an elongated support sheet, a base insulating layer extending in a longitudinal direction of the support sheet and disposed on one surface in a thickness direction of the support sheet, a conductive layer extending in the longitudinal direction and disposed on one surface in the thickness direction of the base insulating layer, and a plurality of areas partitioned in order in the longitudinal direction, wherein the conductive layer has an intermediate portion located between one end portion and the other end portion in the longitudinal direction, and a first measurement mark portion disposed at a boundary portion of the areas adjacent to each other in the longitudinal direction, configured to measure an amount of deviation of the intermediate portion at the boundary portion in a direction perpendicular to the thickness direction and the longitudinal direction, and independent from the conductive layer is included.

Since the wiring circuit board includes the first measurement mark portion, it is possible to measure the amount of deviation of the intermediate portion of the conductive layer and determine the defectiveness of the conductive layer. Therefore, the conductive layer of the wiring circuit board is excellent in reliability.

The present invention (6) includes the wiring circuit board sheet described in (5), wherein the base insulating layer has a second intermediate portion located between one end portion and the other end portion in the longitudinal direction, and a second measurement mark portion configured to measure an amount of deviation of the second intermediate portion at the boundary portion in the perpendicular direction and independent from the base insulating layer is included.

Since the wiring circuit board includes the second measurement mark portion, it is possible to measure the amount of deviation of the intermediate portion of the insulating layer and determine the defectiveness of the insulating layer. Therefore, the insulating layer of the wiring circuit board is excellent in reliability.

The present invention (7) includes the wiring circuit board sheet described in (6), wherein the first measurement mark portion and the second measurement mark portion overlap.

In the wiring circuit board, the configuration of the measurement mark portion becomes compact. Further, of the first measurement mark portion and the second measurement mark portion, when one is detected, the other can be easily detected.

### Effect of the Invention

The method for producing a wiring circuit board of the present invention can accurately measure an amount of deviation of a mask, correct the arrangement of the mask, and further, measure the deviation of a wiring pattern.

In the wiring circuit board sheet of the present invention, it is possible to measure an amount of deviation of an intermediate portion of a conductive layer.

### BRIEF DESCRIPTION OF THE DRAWINGS

FIG. 1 shows a plan view of a wiring circuit board sheet of the present invention.

FIG. 2 shows a side cross-sectional view along an X-X of the wiring circuit board sheet shown in FIG. 1.

FIG. 3 shows a front cross-sectional view along a Y-Y of the wiring circuit board sheet shown in FIG. 1.

FIG. 4 shows an enlarged plan view of a measurement mark portion provided in the wiring circuit board sheet shown in FIG. 1.

FIGS. 5A to 5C show process views of a method for producing the wiring circuit board sheet shown in FIG. 1.

FIG. 5A illustrating a step of forming a base insulating layer,

FIG. 5B illustrating a step of forming a conductive pattern, and

FIG. 5C illustrating a step of forming a cover insulating layer.

FIGS 6A to 6B show process views of a method for producing the wiring circuit board sheet shown in FIG. 2.

FIG. 6A illustrating a step of forming a base insulating layer and

FIG. 6B illustrating a step of forming a conductive pattern.

FIGS 7A to 7B show process views of a method for producing the wiring circuit board sheet shown in FIG. 3;

FIG. 7A illustrating a step of forming a base insulating layer and an insulating measurement mark portion and

FIG. 7B illustrating a step of forming a conductive pattern and a conductive measurement mark portion.

FIGS. 8A to 8C show process views illustrating a step of exposing a photosensitive base precursor layer while moving a mask:

FIG. 8A illustrating a step of disposing a first mask,

FIG. 8B illustrating a step of disposing a second mask, and

FIG. 8C illustrating a step of disposing a third mask.

FIGS. 9A to 9C show a step of exposing a photosensitive base precursor layer through a mask, and show process cross-sectional views along a Z-Z line of FIGS. 8A to 8C;

FIG. 9A illustrating a step of exposing the photosensitive base precursor layer through a first mask,

FIG. 9B illustrating a step of exposing the photosensitive base precursor layer through a second mask, and

FIG. 9C illustrating a step of developing the photosensitive base precursor layer to form an insulating measurement mark portion.

FIGS. 10A to 10C show process views illustrating a step of exposing a photoresist while moving a mask;

FIG. 10A illustrating a step of disposing a fourth mask,

FIG. 10B illustrating a step of disposing a fifth mask, and

FIG. 10C illustrating a step of disposing a sixth mask.

FIGS. 11A to 11D show a step of exposing a photoresist through a mask, and show process cross-sectional views along a Z-Z line of FIGS. 10A to 10C:

FIG. 11A illustrating a step of exposing the photoresist through a fourth mask,

FIG. 11B illustrating a step of exposing the photoresist through a fifth mask,

FIG. 11C illustrating a step of developing the photoresist to form a plating resist, and

FIG. 11D illustrating a step of forming a conductive measurement mark portion by plating using the plating resist.

FIG. 12A shows a plan view of an embodiment in which a first light transmitting pattern of a first mask and a second mask deviates.

FIG. 12B shows a plan view of an insulating measurement mark portion and a base insulating layer corresponding to FIG 12A.

FIG. 13A shows a plan view of an embodiment in which a fourth light shielding pattern of a fourth mask and a fifth mask deviates.

FIG. 13B shows a plan view of a conductive measurement mark portion and a conductive pattern corresponding to FIG. 13A.

FIGS. 14A to 14D show a modified example of the production step shown in FIGS. 11A to 11D, and show an embodiment of forming a conductive pattern and a conductive measurement mark portion by etching:

FIG. 14A illustrating a step of exposing the photoresist through the fourth mask,

FIG. 14B illustrating a step of exposing the photoresist through the fifth mask,

FIG. 14C illustrating a step of developing the photoresist to form an etching resist, and

FIG. 14D illustrating a step of forming a conductive measurement mark portion and a conductive pattern by etching using the etching resist.

FIGS. 15A to 15C show a modified example of moving the same mask:

FIG. 15A illustrating a step of disposing a fifth mask,

FIG. 15B illustrating a step of moving the fifth mask, and

FIG. 15C illustrating an embodiment for forming three measurement mark portions in each of both end portions in a width direction of a wiring circuit board sheet.

FIG. 16 shows a plan view of a wiring circuit board assembly sheet which is a modified example of a wiring circuit board sheet including a plurality of wiring circuit boards.

FIGS. 17A to 17C show a modified example in which a light shielding mark is spaced apart from the end edge in a longitudinal direction of a mask:

FIG. 17A illustrating a step of disposing a fourth mask,

FIG. 17B illustrating a step of disposing a fifth mask, and

FIG. 17C illustrating a step of producing a wiring circuit board sheet.

FIGS. 18A to 18C show a modified example in which a conductive measurement mark portion includes only a first conductive mark:

FIG. 18A illustrating a step of disposing a fourth mask,

FIG. 18B illustrating a step of disposing a fifth mask, and

FIG. 18C illustrating a step of producing a wiring circuit board sheet.

FIGS. 19A to 19C show a modified example of having two third conductive marks:

FIG. 19A illustrating a step of disposing a fourth mask,

FIG. 19B illustrating a step of disposing a fifth mask, and

FIG. 19C illustrating a step of producing a wiring circuit board sheet.

FIGS. 20A to 20C show a modified example in which a conductive measurement mark portion has a double rectangular frame shape:

FIG. 20A illustrating a step of disposing a fourth mask,

FIG. 20B illustrating a step of disposing a fifth mask, and

FIG. 20C illustrating a step of producing a wiring circuit board sheet.

FIGS. 21A to 21C show a modified example in which a conductive measurement mark portion hits a double circular ring shape:

FIG. 21A illustrating a step of disposing a fourth mask,

FIG. 21B illustrating a step of disposing a fifth mask, and

FIG. 21C illustrating a step of producing a wiring circuit board sheet.

FIGS. 22A to 22C show a modified example in which a conductive measurement mark portion includes two U-shaped portions:

FIG. 22A illustrating a step of disposing a fourth mask,

FIG. 22B illustrating a step of disposing a fifth mask, and

FIG. 22C illustrating a step of producing a wiring circuit board sheet.

FIGS. 23A to 23D show a modified example in which the same mask is moved from one side to the other side in a longitudinal direction:

FIG. 23A illustrating a step of disposing a mask in one end portion in the longitudinal direction of a photoresist,

FIG. 23B illustrating a step of moving the same mask,

FIG. 23C illustrating a step of moving the same mask, and

FIG. 23D illustrating a plan view of a wiring circuit board sheet including a linear conductive pattern.

### EMBODIMENT OF THE INVENTION

### One Embodiment

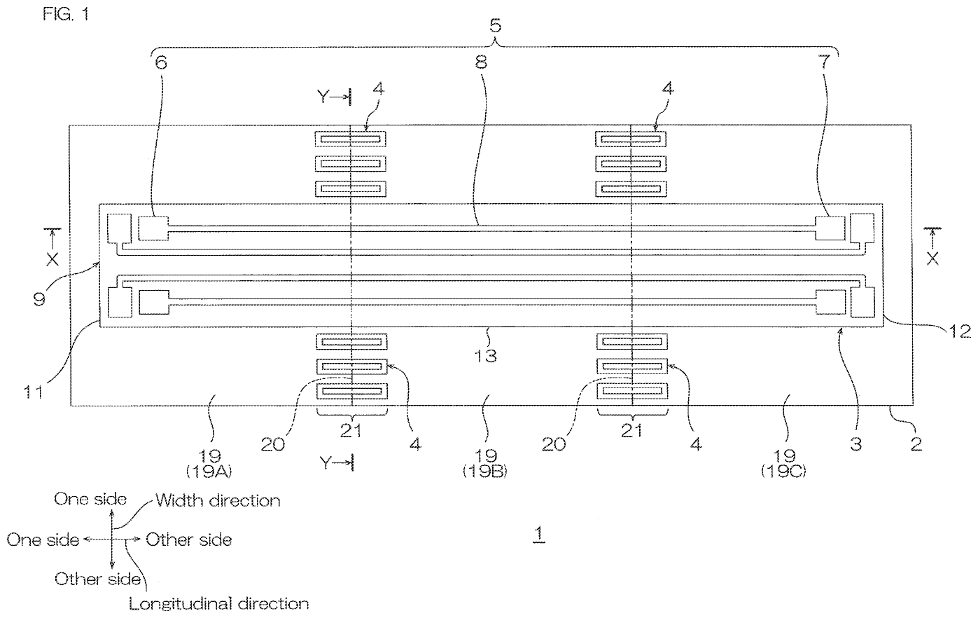

One embodiment of a wiring circuit board sheet and a method for producing a wiring circuit board of the present invention is described with reference to FIGS. 1 to 13B.

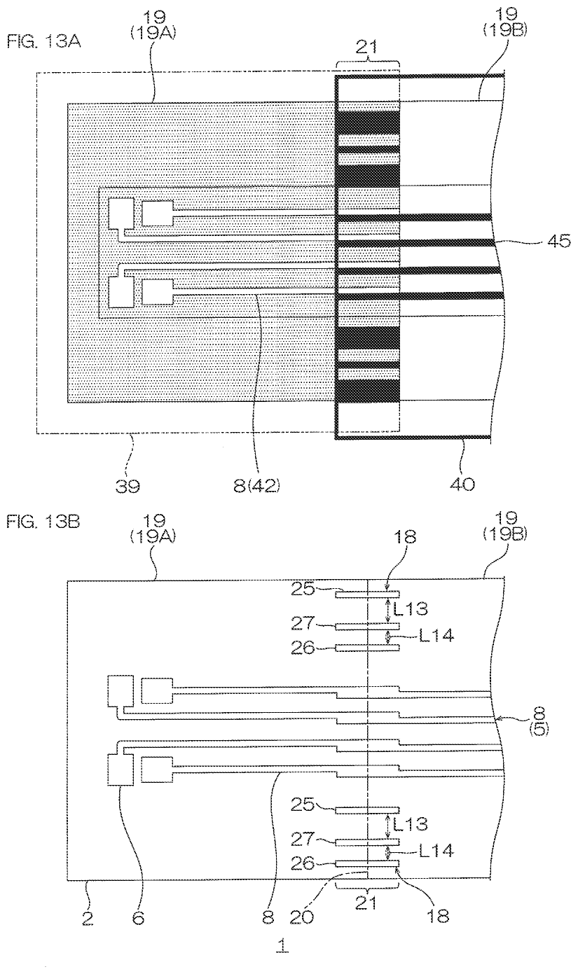

In FIG 1. in order to clearly show the shape of a conductive pattern 5 and a base insulating layer 9 (described later), a cover insulating layer 10 (described later) is omitted. Further, in FIGS. 13A to 13B, in order to clearly show the arrangement of the conductive pattern 5 and a conductive measurement mark portion 18 (described later), the base insulating layer 9 is omitted.

As shown in FIGS. 1 to 3, a wiring circuit board sheet 1 has a predetermined thickness, and is a generally rectangular sheet when viewed from the top extending along a longitudinal direction (direction perpendicular to a thickness direction). The wiring circuit board sheet 1 includes one support sheet 2, one wiring circuit board 3, and a plurality of measurement mark portions 4.

The support sheet 2 has the same shape as the wiring circuit board sheet 1 when viewed front the top. The support sheet 2 is not particularly limited as long as it can support (secure) the wiring circuit board 3 from the other side in the thickness direction. An example of the support sheet 2 includes a sheet having toughness, flexibility, and/or rigidity. Examples of the support sheet 2 include a metal plate, a resin sheet, and paper. An example of the metal plate includes a stainless steel plate. An example of the resin sheet includes a polyimide sheet. Further, the support sheet 2 is a single layer or a multilayer (laminate). A thickness of the support sheet 2 is not particularly limited. The thickness of the support sheet 2 is, for example, 5 μm or more, preferably 10 μm or more, and for example, 500 μm or less, preferably 200 μm or less.

The wiring circuit board 3 is disposed in the inner-side portion of the circumferential end portion in a plane direction (direction perpendicular to the thickness direction) in one surface in the thickness direction of the support sheet 2. The wiring circuit board 3 has a generally rectangular flat plate shape extending along the longitudinal direction.

The wiring circuit board 3 includes the conductive pattern 5. The conductive pattern 5 is disposed over the longitudinal direction in the wiring circuit board 3. The conductive pattern 5 extends in the longitudinal direction. The conductive pattern 5 includes a conductive one end portion 6, a conductive other end portion 7, and a conductive intermediate portion 8 as one example of an intermediate portion.

The conductive one end portion 6 is located in one end portion in the longitudinal direction of the conductive pattern 5. The conductive one end portion 6 includes, for example, a one-side terminal. In the wiring circuit board 3, the plurality of one-side terminals are arranged to be adjacent to each other at a distance in the longitudinal direction and a width direction (one example of a direction perpendicular to the longitudinal direction and the thickness direction). Each of the plurality of one-side terminals has, for example, a generally rectangular land shape.

The conductive other end portion 7 is located in the other end portion in the longitudinal direction of the conductive pattern 5. The conductive other end portion 7 includes, for example, an other-side terminal. In the wiring circuit board 3, the plurality of other-side terminals are arranged to be adjacent to each other at a distance in the longitudinal direction and the width direction. Each of the plurality of other-side terminals has, for example, a generally rectangular land shape.

The conductive intermediate portion 8 is located in the intermediate portion in the longitudinal direction of the conductive pattern 5. The conductive intermediate portion 8 is located between the conductive one end portion 6 and the conductive other end portion 7. The conductive intermediate portion 8 extends in the longitudinal direction. The conductive intermediate portion 8 includes a narrower wire than the one-side terminal and the other-side terminal. The wire is continuous to the one-side terminal and the other-side terminal. Thus, the wire connects the one-side terminal to the other-side terminal in the longitudinal direction. In the wiring circuit board 3, the plurality of wires are arranged to be adjacent to each other at a distance in the width direction. The plurality of wires are parallel with each other. Each of the plurality of wires has a generally linear shape when viewed from the top along the longitudinal direction.

A length in the longitudinal direction of the conductive pattern 5 is, for example, 300 mm or more, preferably, 600 mm or more, more preferably, 1000 mm or more, and for example, 10,000 mm or less. The length in the longitudinal direction of the conductive pattern 5 is a distance between one end edge of the conductive one end portion 6 and the other end edge of the conductive other end portion 7. When the length in the longitudinal direction of the conductive pattern 5 is the above-described lower limit or more, the wiring circuit board 3 is suitable as an elongated wiring circuit board in which a transmission distance of an electric signal and/or the transmission distance of a power supply current are/is long.

A width of the wire in the conductive pattern 5 is, for example, 100 μm or less, preferably 90 μm or less, more preferably 80 μm or less, and for example, 5 μm or more. An interval between the wires adjacent to each other is, for example, 100 μm or less, preferably 90 μm or less, more preferably 80 μm or less, and for example, 5 μm or more. When the width and/or the interval are/is the above-described upper limit or less, it is suitable as the narrow wiring circuit board 3.

An example of a material for the conductive pattern 5 includes a conductor. An example of the conductor includes copper. A thickness of the conductive pattern 5 is, for example, 5 μm or more and 100 μm or less.

The wiring circuit board 3 further includes the base insulating layer 9 and the cover insulating layer 10 as one example of an insulating layer adjacent to the conductive pattern 5 on the other side and one side in the thickness direction, respectively. Specifically, the wiring circuit board 3 includes the base insulating layer 9, the conductive pattern 5 described above which is disposed on one surface in the thickness direction of the base insulating layer 9, and the cover insulating layer 10 disposed on one surface in the thickness direction of the base insulating layer 9 so as to expose the one-side terminal and the other-side terminal of the conductive pattern 5 and cover one surface in the thickness direction and both side surfaces in the plane direction of the wire of the conductive pattern 5.

The base insulating layer 9 is disposed on one surface in the thickness direction of the support sheet 2. The base insulating layer 9 has the same outer shape as the wiring circuit board 3.

The base insulating layer 9 integrally includes a base one end portion 11 as one example of one end portion, a base other end portion 12 as one example of the other end portion, and a base intermediate portion 13 as one example of a second intermediate portion. The base one end portion 11 includes the conductive one end portion 6 when viewed from the top. The base other end portion 12 includes the conductive other end portion 7 when viewed from the top. The base intermediate portion 13 includes the conductive intermediate portion 8 when viewed from the top.

An example of a material for the base insulating layer 9 includes a resin having insulating properties. An example of the resin includes polyimide. A thickness of the base insulating layer 9 is, for example, 3 μm or more and 50 μm or less.

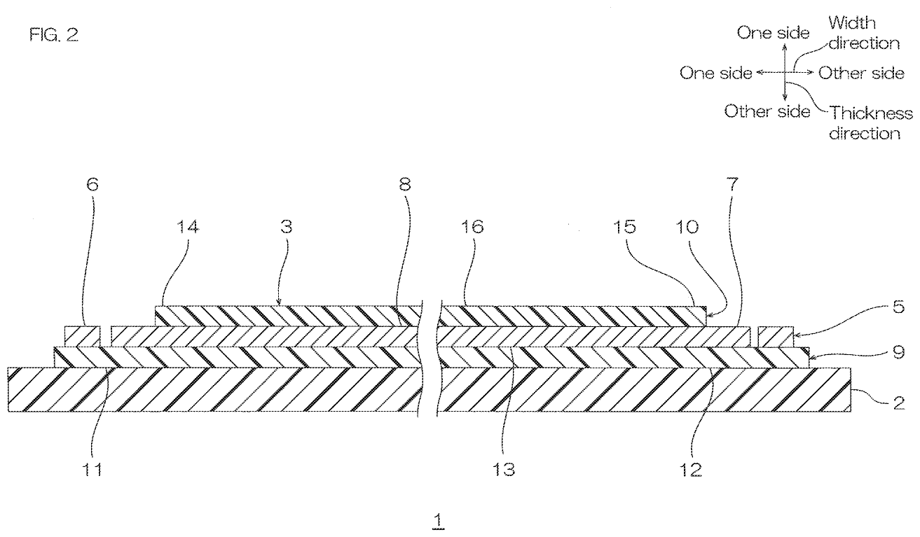

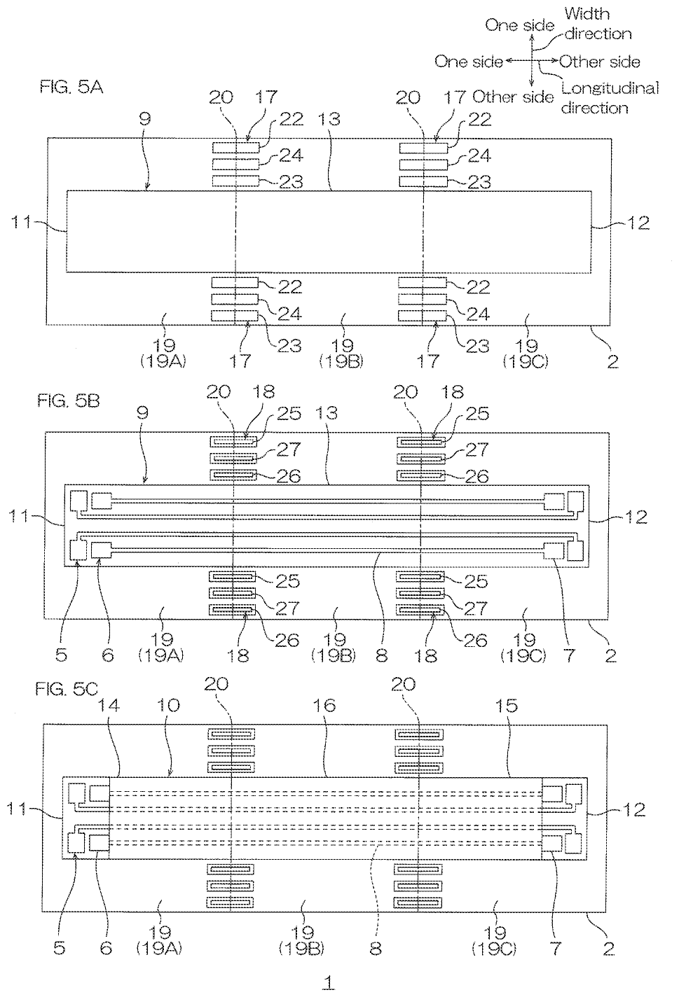

As shown in FIGS. 2 and 5C, the cover insulating layer 10 includes a cover one end portion 14, a cover other end portion 15, and a cover intermediate portion 16. The cover one end portion 14 is included in the base one end portion 11 when viewed from the top. The cover other end portion 15 is included in the base other end portion 12 when viewed from the top. The cover intermediate portion 16 is included in the base intermediate portion 13 when viewed from the top. An example of a material for the cover insulating layer 10 includes a resin having insulating properties. An example of the resin includes polyimide. A thickness of the cover insulating layer 10 is, for example, 3 μm or more and 50 μm or less.

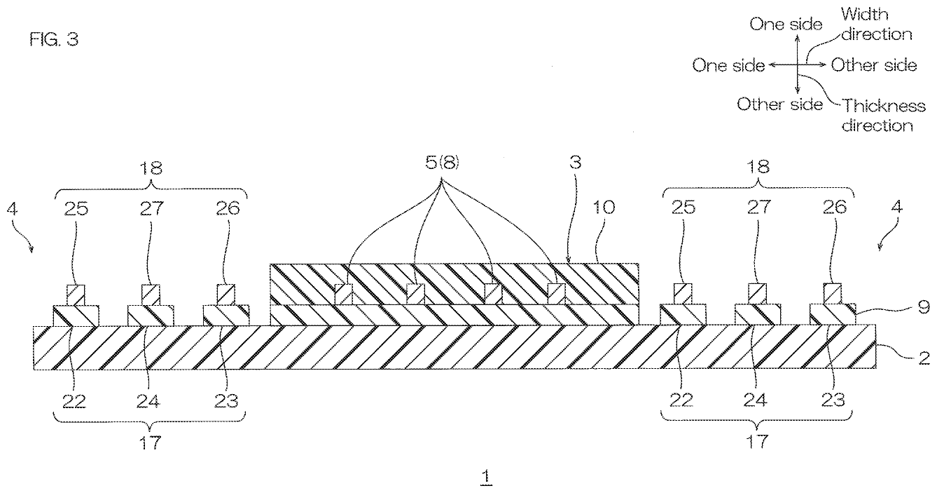

As shown in FIGS. 1 and 3, the measurement mark portion 4 is disposed in both end portions in the width direction on one surface in the thickness direction of the support sheet 2.

The plurality of (two) measurement mark portions 4 in one end portion in the width direction of the support sheet 2 are spaced apart from each other in the longitudinal direction.

The plurality of (two) measurement mark portions 4 in the other end portion in the width direction of the support sheet 2 are spaced apart from each other in the longitudinal direction.

In the wiring circuit board sheet 1, the two measurement mark portions 4 which are oppositely disposed in the width direction define a boundary 20 of sheet areas 19 adjacent to each other in the longitudinal direction. The boundary 20 is a line segment passing through one measurement mark portion 4 and the other measurement mark portion 4. The boundary 20 is along the width direction. In FIGS. 1 and 5A to 5C, the boundary 20 is shown by a phantom line, and in the actual wiring circuit board sheet 1, the outer shape of the boundary 20 may not be clearly visually recognized.

Further, a peripheral region including the boundary 20 is referred to as a boundary portion 21. The measurement mark portion 4 is located in the boundary portion 21.

Then, each (one) sheet area 19 is partitioned by the plurality of (two) boundaries 20 spaced apart in the longitudinal direction. The plurality of (three) sheet areas 19 are sequentially partitioned in the longitudinal direction. In the wiring circuit board sheet 1, one wiring circuit board 3 is disposed over the plurality of (three) continuous sheet areas 19.

As shown in FIGS. 1 and 5C, for example, the three sheet areas 19 described above are referred to as a first sheet area 19A, a second sheet area 19B, and a third sheet area 19C in order from one side toward the other side in the longitudinal direction. In this case, the conductive one end portion 6, the base one end portion 11, and the cover one end portion 14 are disposed in the first sheet area 19A. The conductive other end portion 7, the base other end portion 12, and the cover other end portion 15 are disposed in the third sheet area 19C. Meanwhile, the conductive intermediate portion 8, the base intermediate portion 13, and the cover intermediate portion 16 are disposed over the first sheet area 19A to the third sheet area 19C (all of the plurality of sheet areas 19).

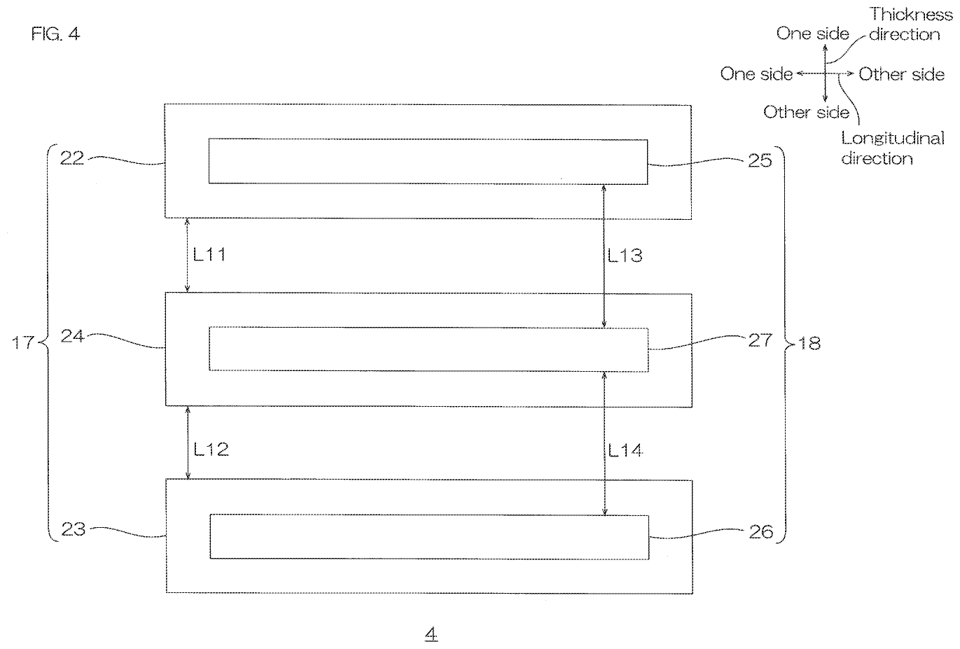

As shown in FIG. 4, the measurement mark portion 4 includes an insulating measurement mark portion 17 as one example of a second measurement mark portion, and a conductive measurement mark portion 18 as one example of a first measurement mark portion.

The insulating measurement mark portion 17 is disposed at the outside in the width direction of the base insulating layer 9 at a distance. The insulating measurement mark portion 17 is independent from the base insulating layer 9.

The insulating measurement mark portion 17 sequentially includes a first insulating mark 22 as one example of one portion, a third insulating mark 24 as one example of a middle portion, and a second insulating mark 23 as one example of the other portion from one side toward the other side in the width direction. The first insulating mark 22, the third insulating mark 24, and the second insulating mark 23 are spaced apart from each other in the width direction. The first insulating mark 22, the third insulating mark 24, and the second insulating mark 23 are overlapped with each other when projected in the width direction.

Thus, the first insulating mark 22 and the second insulating mark 23 are arranged to be opposed to each other at a distance in the width direction. The third insulating mark 24 is disposed between the first insulating mark 22 and the second insulating mark 23. The third insulating mark 24 is spaced apart from the first insulating mark 22 and the second insulating mark 23.

Each of the first insulating mark 22, the third insulating mark 24, and the second insulating mark 23 has a generally linear shape when viewed from the top along the longitudinal direction of the base insulating layer 9.

The first insulating mark 22 and the second insulating mark 23 are one example of one insulating mark portion. The third insulating mark 24 is one example of another insulating mark portion.

The conductive measurement mark portion 18 is disposed at the outside in the width direction of the conductive pattern 5 at a distance. The conductive measurement mark portion 18 is electrically independent from the conductive pattern 5.

The conductive measurement mark portion 18 sequentially includes a first conductive mark 25 as one example of one portion, a third conductive mark 27 as one example of a middle portion, and a second conductive mark 26 as one example of the other portion from one side toward the other side in the width direction. Each of the first conductive mark 25, the third conductive mark 27, and the second conductive mark 26 is included in each of the first insulating mark 22, the third insulating mark 24, and the second insulating mark 23, respectively when viewed from the top. The first conductive mark 25 and the second conductive mark 26 are arranged to be opposed to each other at a distance in the width direction. The third conductive mark 27 is disposed between the first conductive mark 25 and the second conductive mark 26. The third conductive mark 27 is spaced apart from the first conductive mark 25 and the second conductive mark 26.

Specifically, the first conductive mark 25 is along the longitudinal direction of the conductive pattern 5, and has a generally smaller linear shape than the first insulating mark 22 when viewed from the top. The length in the longitudinal direction of the first conductive mark 25 is shorter than that of the first insulating mark 22. When projected in the width direction, the first conductive mark 25 is not overlapped with both end portions in the longitudinal direction of the first insulating mark 22.

The third conductive mark 27 is parallel with the first conductive mark 25, and has a generally smaller linear shape than the third insulating mark 24 when viewed from the top. The length in the longitudinal direction of the third conductive mark 27 is shorter than that of the third insulating mark 24. When projected in the width direction, the third conductive mark 27 is not overlapped with both end portions in the longitudinal direction of the third insulating mark 24.

The second conductive mark 26 is parallel with the first conductive mark 25, and has a generally smaller linear shape than the second insulating mark 23 when viewed from the top. The length in the longitudinal direction of the second conductive mark 26 is shorter than that of the second insulating mark 23. When projected in the width direction, the second conductive mark 26 is not overlapped with both end portions in the longitudinal direction of the second insulating mark 23.

The first conductive mark 25 and the second conductive mark 26 are one example of one conductive mark portion. The third conductive mark 27 is one example of another conductive mark portion.

Next, a method for producing the wiring circuit hoard sheet 1 is described.

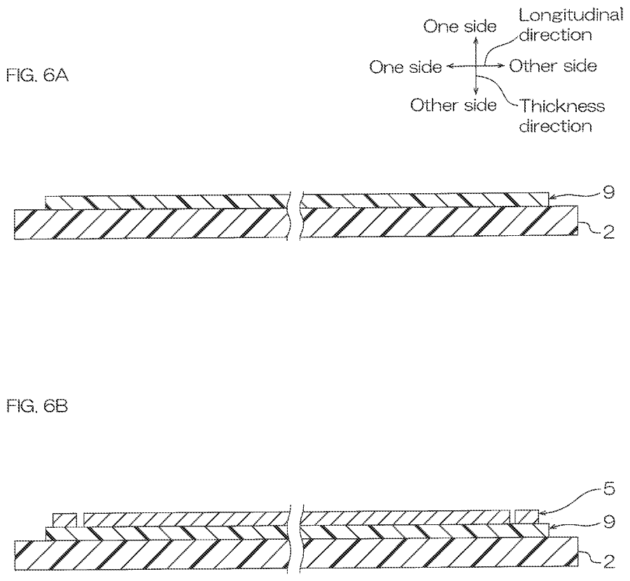

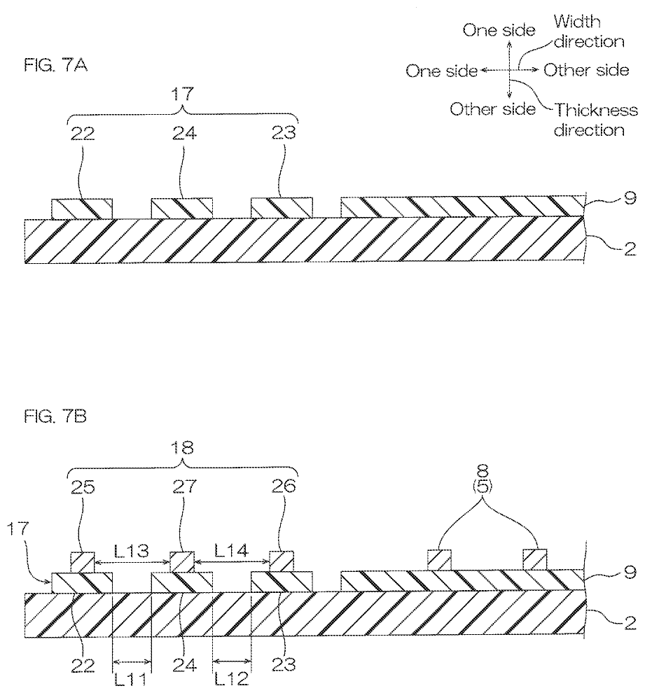

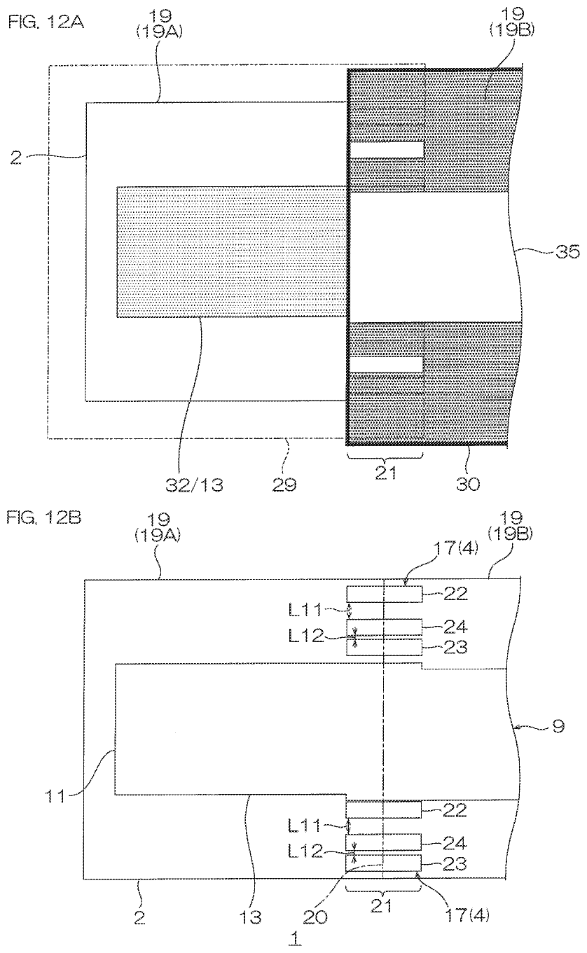

As shown in FIGS. 2 to 3 and 6A to 7B, the method includes a first step of preparing the support sheet 2, a second step of forming the base insulating layer 9 and the insulating measurement mark portion 17 (ref. FIGS. 6A and 7A), a third step of measuring an amount of deviation of masks 29, 30, and 31 (ref: FIGS. 4 and 12B), a fourth step of forming the conductive pattern 5 and the conductive measurement mark portion 18 (ref. FIGS. 6B and 7B), a fifth step of measuring an amount of deviation of masks 39, 40, and 41 (ref: FIGS. 4 and 13B), and a sixth step of forming the cover insulating layer 10 (ref. FIGS. 2 to 3). In one embodiment, the first to the sixth steps are carried out in sequence.

### First Step

In the first step, the elongated support sheet 2 is prepared.

### Second step

As shown in FIGS. 6A and 7A, subsequently, in the second step, the base insulating layer 9 and the insulating measurement mark portion 17 are formed by photolithography.

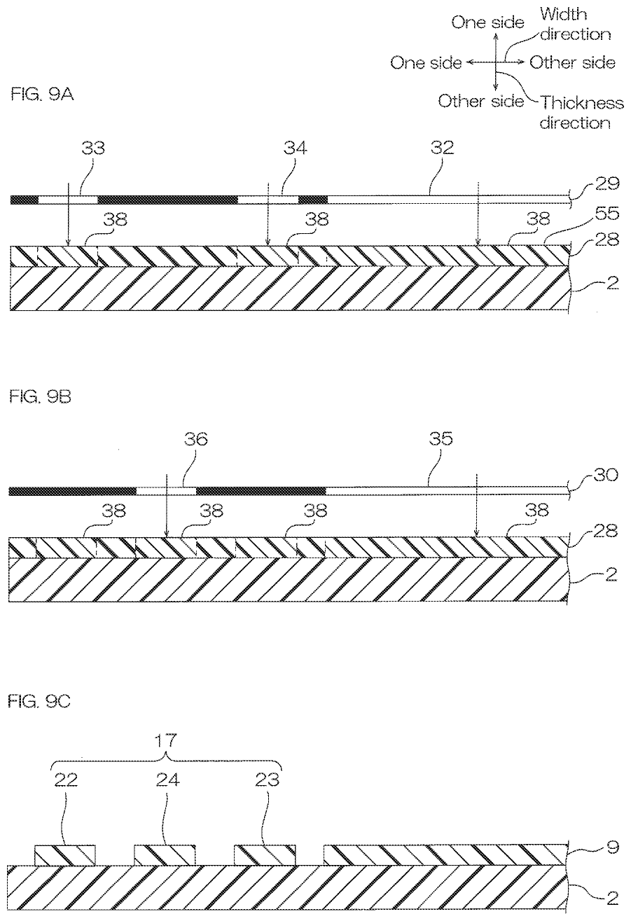

In the photolithography, first, as shown in FIG. 9A, a photosensitive base precursor layer 28 as one example of a photosensitive resin insulating layer is disposed on the entire one surface in the thickness direction of the support sheet 2. Specifically, a varnish of a photosensitive resin is applied to one surface in the thickness direction of the support sheet 2, and then, dried to form the elongated photosensitive base precursor layer 28.

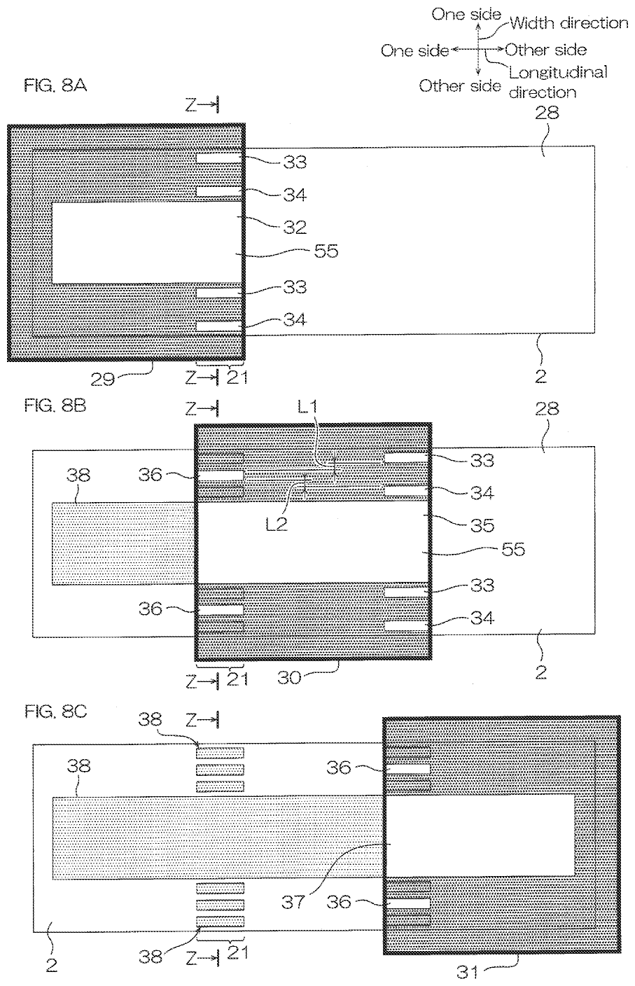

Subsequently, as shown in FIGS. 8A to 9C, the photosensitive base precursor layer 28 is exposed a plurality of times (three times) while the three masks 29, 30, and 31 are sequentially arranged in the longitudinal direction, and the photosensitive base precursor layer 28 after exposure is developed.

As shown in FIGS. 8A to 8C, the three masks 29, 30, and 31 are the first mask 29, the second mask 30, and the third mask 31, respectively. Each of the first mask 29, the second mask 30, and the third mask 31 has a generally rectangular outer shape when viewed from the top.

As shown in FIGS. 8A and 9A, the first mask 29 includes a first light transmitting pattern 32, a first light transmitting mark 33, and a second light transmitting mark 34.

The first light transmitting pattern 32 corresponds to the base one end portion 11 and the base intermediate portion 13 shown in FIG. 5A. The longitudinal other end edge of the first light transmitting pattern 32 is included in the longitudinal other end edge of the first mask 29. The first light transmitting pattern 32 extends from the longitudinal other end edge of the first mask 29 to the middle in the longitudinal direction toward one side.

As shown in FIG. 8A, the first light transmitting mark 33 corresponds to the first insulating mark 22 shown in FIG. 5A. The second light transmitting mark 34 corresponds to the second insulating mark 23 shown in FIG. 5A.

The first light transmitting mark 33 and the second light transmitting mark 34 are disposed in the longitudinal other end portion of the first mask 29. Each of the longitudinal other end edges of the first light transmitting mark 33 and the second light transmitting mark 34 is included in the longitudinal other end edge of the first mask 29. Each of the first light transmitting mark 33 and the second light transmitting mark 34 extends from the longitudinal other end edge of the first mask 29 to the middle in the longitudinal direction toward one side. A shape of the first light transmitting mark 33 and the second light transmitting mark 34 is the same as that of the first insulating mark 22 and the second insulating mark 23 shown in FIG. 5A. Further, both the first light transmitting mark 33 and the second light transmitting mark 34 are disposed in both end portions in the width direction of the first mask 29.

As shown in FIGS. 8B and 9B, the second mask 30 includes a second light transmitting pattern 35, a third light transmitting mark 36, the first light transmitting mark 33, and the second light transmitting mark 34.

The second light transmitting pattern 35 corresponds to the base intermediate portion 13 shown in FIG. 5A. The second light transmitting pattern 35 extends from one end edge to the other end edge in the longitudinal direction of the second mask 30.

The third light transmitting mark 36 shown in FIG. 8B corresponds to the third insulating mark 24 shown in FIG. 5A. The third light transmitting mark 36 is disposed in the longitudinal one end portion of the second mask 30. The longitudinal one end edge of the third light transmitting mark 36 is included in the longitudinal one end edge of the second mask 30. The third light transmitting mark 36 extends from the longitudinal one end edge of the second mask 30 to the middle in the longitudinal direction toward the other side. A shape of the third light transmitting mark 36 is the same as that of the third insulating mark 24. The third light transmitting mark 36 is disposed in both end portions in the width direction of the second mask 30.

The first light transmitting mark 33 and the second light transmitting mark 34 (ref: FIG. 8A) in the second mask 30 shown in FIG. 8B have the same configuration (shape, arrangement, etc.) as the first light transmitting mark 33 and the second light transmitting mark 34 in the first mask 29.

Further, in the second mask 30, the third light transmitting mark 36 is offset with the first light transmitting mark 33 and the second light transmitting mark 34 when projected in the longitudinal direction. Specifically, the third light transmitting mark 36 is located between the first light transmitting mark 33 and the second light transmitting mark 34 when projected in the longitudinal direction.

When projected in the longitudinal direction, a width direction distance L1 between the first light transmitting mark 33 and the third light transmitting mark 36, and a width direction length L2 between the third light transmitting mark 36 and the second light transmitting mark 34 are a length that serves as a reference for measurement of the amount of deviation to be described later. That is, the width direction length L1 and L2 are not dependent on the amount of deviation to be described later. That is, the width direction length L1 and L2 are an inherent amount in the second mask 30.

As shown in FIG. 8C, the third mask 31 includes a third light transmitting pattern 37 and the third light transmitting mark 36.

The third light transmitting pattern 37 corresponds to the base other end portion 12 and the base intermediate portion 13 shown in FIG. 5A. The third light transmitting pattern 37 extends from the longitudinal one end edge of the third mask 31 to the middle in the longitudinal direction toward the other end edge.

The third light transmitting mark 36 in the third mask 31 has the same configuration (shape, arrangement, etc.) as the third light transmitting mark 36 in the second mask 30.

In the three masks 29, 30, and 31 described above, each of the light transmitting pattern and the light transmitting mark is a light transmitting portion that transmits light in the next exposure. In the three masks 29, 30, and 31, a portion other than the light transmitting portion is a light shielding portion for blocking light.

Then, as shown in FIGS. 8A and 9A, in this photolithography, first, the first mask 29 is disposed on one side in the thickness direction of the longitudinal one end portion of the photosensitive base precursor layer 28. Subsequently, the photosensitive base precursor laser 28 is exposed through the first mask 29 (first exposure). Then, a latent image 38 corresponding to the first light transmitting pattern 32, the first light transmitting mark 33, and the second light transmitting mark 34 is formed in the photosensitive base precursor layer 28. The latent image 38 is formed by irradiating light transmitting through the light transmitting pattern and the light transmitting mark to the photosensitive base precursor layer 28.

Then, as shown in FIGS. 8B and 9B, in this photolithography, instead of the first mask 29, the second mask 30 is disposed on one side in the thickness direction of the photosensitive base precursor layer 28. The second mask 30 is disposed on the other side in the longitudinal direction with respect to the arrangement portion of the first mask 29, and at that time, the longitudinal one end portion of the second mask 30 is disposed with respect to the photosensitive base precursor layer 28 so as to overlap in the thickness direction with an opposing portion 55 facing the longitudinal other end portion of the first mask 29 in the photosensitive base precursor laser 28. Subsequently, the photosensitive base precursor layer 28 is exposed through the second mask 30 (second exposure). Then, the latent image 38 corresponding to the second light transmitting pattern 35, the third light transmitting mark 36, the first light transmitting mark 33, and the second light transmitting mark 34 is formed in the photosensitive base precursor laser 28.

In the latent image 38, the opposing portion 55 corresponding to the first light transmitting pattern 32 is overlapped with the portion facing the second light transmitting pattern 35.

On the other hand, the latent image 38 (ref: FIG. 9A) corresponding to the first light transmitting mark 33 and the second light transmitting mark 34 at the time of the first exposure is not overlapped with (is offset with) the latent image 38 (ref: FIG. 9B) corresponding to the third light transmitting mark 36 at the time of the second exposure. Specifically, the latent image 38 (ref. FIG. 9A) corresponding to the first light transmitting mark 33 and the second light transmitting mark 34 at the time of the first exposure, and the latent image 38 (ref: FIG. 9B) corresponding to the third light transmitting mark 36 at the time of the second exposure are spaced apart from each other in the width direction.

Thus, in the boundary portion 21 between the first sheet area 19A and the second sheet area 19B, the latent image 38 formed using the third light transmitting mark 36 by the present exposure is added to the latent image 38 formed using the first light transmitting mark 33 and the second light transmitting mark 34 by the previous exposure.

Thereafter, as shown in FIG. 8C, in this method, instead of the second mask 30, the third mask 31 is disposed on one side in the thickness direction of the photosensitive base precursor layer 28. The third mask 31 is disposed on the other side in the longitudinal direction with respect to the arrangement portion of the second mask 30, and at that time, the longitudinal one end portion of the third mask 31 is disposed with respect to the photosensitive base precursor layer 28 so as to overlap in the thickness direction with the opposing portion 55 facing the longitudinal other end portion of the second mask 30 in the photosensitive base precursor layer 28. Subsequently, the photosensitive base precursor layer 28 is exposed through the third mask 31. Then, the latent image 38 corresponding to the third light transmitting pattern 37 and the third light transmitting mark 36 is formed in the photosensitive base precursor layer 28.

As shown in FIG. 8C, in the latent image 38, the opposing portion 55 corresponding to the second light transmitting pattern 35 is overlapped with the portion facing the third light transmitting pattern 37.

On the other hand, the latent image 38 (ref. FIG. 8B) corresponding to the first light transmitting mark 33 and the second light transmitting mark 34 at the time of the second exposure is not overlapped with (is offset, with) the latent image 38 (ref: FIG 8C) corresponding to the third light transmitting mark 36 at the time of the third exposure. Specifically, the latent image 38 (ref: FIG 8B) corresponding to the first light transmitting mark 33 and the second light transmitting mark 34 at the time of the second exposure, and the latent image 38 (ref FIG. 8C) corresponding to the third light transmitting mark 36 at the time of the third exposure are spaced apart from each other in the width direction. Thus, in the boundary portion 21 between the second sheet area 19B and the thud sheet area 19C, the latent image 38 formed using the thud light transmitting mark 36 by the present exposure is added to the latent image 38 formed using the first light transmitting mark 33 and the second light transmitting mark 34 by the previous exposure.

Thereafter, the photosensitive base precursor layer 28 in which the latent image 38 described above is formed is developed and heated, if necessary.

Thus, as shown in FIG. 5A, the base insulating layer 9 and the insulating measurement mark portion 17 are formed at the same time.

### Third Step

Thereafter, an amount of deviation of the masks 29, 30, and 31 shown in FIGS. 8A to 8C is measured.

FIG. 12A shows an embodiment in which in the boundary portion 21 between the first sheet area 19A and the second sheet area 19B, the first light transmitting pattern 32 of the first mask 29, and the second light transmitting pattern 35 of the second mask 30 deviate. Further. FIG. 12B shows the base insulating layer 9 and the insulating measurement mark portion 17 formed by the first mask 29 and the second mask 30 described above.

As shown in FIG. 12B, first, in the third step, the insulating measurement mark portion 17 in the boundary portion 21 between the first sheet area 19A and the second sheet area 19B is detected.

Subsequently, a width direction distance L11 between the first insulating mark 22 and the third insulating mark 24 in the insulating measurement mark portion 17 is measured. Then, the distance L11 is compared with the width direction distance L1 (ref: FIG. 8B) (known) between the first light transmitting mark 33 and the third light transmitting mark 36. As shown in FIG 12A, a difference between the distance L11 and the width direction distance L1 is obtained as a width direction deviation of the longitudinal other end portion of the first light transmitting pattern 32 of the first mask 29 with the longitudinal one end portion of the second light transmitting pattern 35 of the second mask 30. As shown in FIG. 12B, this deviation corresponds to a deviation between the end edge in the width direction of the base intermediate portion 13 of the first sheet area 19A and the end edge in the width direction of the base intermediate portion 13 of the second sheet area 19B in the opposing portion 55 of the photosensitive base precursor layer 28.

At the same time, a width direction distance L12 between the third insulating mark 24 and the second insulating mark 23 is measured. Then, the distance L12 is compared with the width direction length L2 (ref: FIG. 8B) (known) between the third light transmitting mark 36 and the second light transmitting mark 34. As shown in FIG. 12A, a difference between the distance L12 and the width direction length L2 is obtained as a width direction deviation of the longitudinal other end portion of the first light transmitting pattern 32 of the first mask 29 with the longitudinal one end portion of the second light transmitting pattern 35 of the second mask 30. As shown in FIG. 12B, this deviation corresponds to a deviation between the end edge in the width direction of the base intermediate portion 13 of the first sheet area 19A and the end edge in the width direction of the base intermediate portion 13 of the second sheet area 19B.

The measurement described above is carried out in the insulating measurement mark portion 17 in both end portions in the width direction, and also carried out in the insulating measurement mark portion 17 of the boundary portion 21 between the second sheet area 19B and the third sheet area 19C.

Thereafter, the position in the width direction of the masks 29, 30, and 31 with respect to the photosensitive base precursor layer 28 in which the formation of the base insulating layer 9 is scheduled next is adjusted based on the deviation of the masks 29, 30, and 31.

When the deviation of the base intermediate portion 13 described above is within the range of tolerances, the following fourth step or later is carried out. On the other hand, when the deviation of the end edge in the width direction of the base intermediate portion 13 is outside the range of tolerances, the following fourth step and later is not carried out and excluded from a production target (production line). That is, when the wiring circuit board sheet 1 is a defective component, the following fourth step and later is not carried out and excluded from the production target (production line). Thus, it is possible to direct a material for the conductive pattern 5 in the fifth step, and a material for the cover insulating layer 10 in the sixth step to the production of a non-defective conductive pattern 5 and cover insulating layer 10.

### Fourth Step

In the fourth step, as shown in FIGS. 5B and 7B, the conductive pattern 5 and the conductive measurement mark portion 18 are formed.

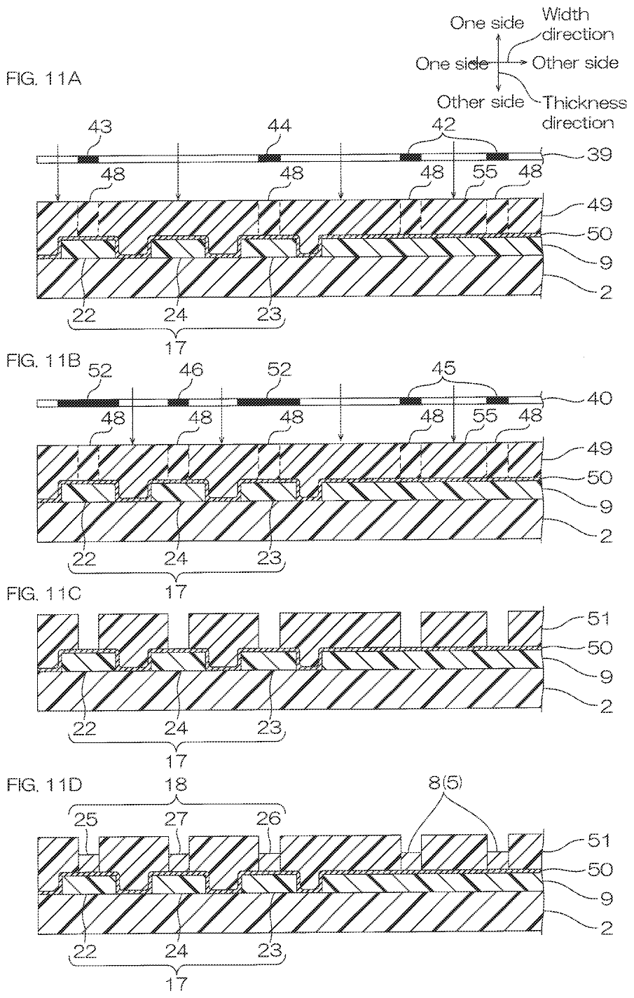

In the fourth step, first, as shown in FIG. 11A, a seed film 50 is formed on the surfaces (including one surface in the thickness direction) of the support sheet 2, the base insulating layer 9, and the insulating measurement mark portion 17.

Subsequently, as shown in FIGS. 11A to 11C, a plating resist 51 is formed by photolithography.

In the photolithography, as shown in FIG. 11A, first, a photoresist 49 is disposed on the surface of the seed film 50. Specifically, a photosensitive dry film resist is laminated on the surface of the seed film 50 to form the photoresist 49 on the entire surface of the seed film 50.

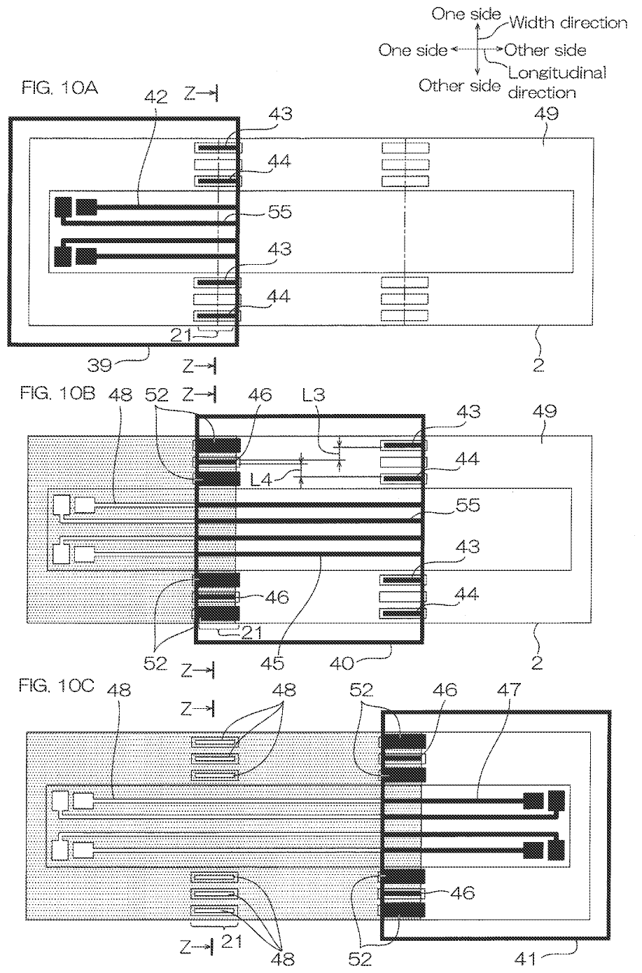

Thereafter, as shown in FIGS. 10A to 11B, the photoresist 49 is exposed a plurality of times while the three masks 39, 40, and 41 are sequentially arranged in the longitudinal direction.

As shown in FIGS. 10A to 10C, the three masks 39, 40, and 41 are the fourth mask 39, the fifth mask 40, and the sixth mask 41, respectively. Each of the fourth mask 39, the fifth mask 40, and the sixth mask 41 has a generally rectangular outer shape when viewed from the top.

As shown in FIG. 10A, the fourth mask 39 includes a fourth light shielding pattern 42, a fourth light shielding mark 43, and a fifth light shielding mark 44.

The fourth light shielding pattern 42 corresponds to the conductive one end portion 6 and the conductive intermediate portion 8 shown in FIG. 5B. The longitudinal other end edge of the fourth light shielding pattern 42 is included m the longitudinal other end edge of the fourth mask 39. The fourth light shielding pattern 42 extends from the longitudinal other end edge of the fourth mask 39 to the middle in the longitudinal direction toward one side.

The fourth light shielding mark 43 shown in FIG. 10A corresponds to the first conductive mark 25 shown in FIG. 5B. The fifth light shielding mark 44 corresponds to the second conductive mark 26 shown in FIG. 5B.

The fourth light shielding mark 43 and the fifth light shielding mark 44 are disposed in the longitudinal other end portion of the fourth mask 39. Each of the longitudinal other end edges of the fourth light shielding mark 43 and the fifth light shielding mark 44 is included in the longitudinal other aid edge of the fourth mask 39. Each of the fourth light shielding mark 43 and the fifth light shielding mark 44 extends from the longitudinal other end edge of the fourth mask 39 to the middle in the longitudinal direction toward one side. A shape of the fourth light shielding mark 43 and the fifth light shielding mark 44 is the same as that of the first conductive mark 25 and the second conductive mark 26 shown in FIG. 5B. Further, both the fourth light shielding mark 43 and the fifth light shielding mark 44 are disposed in both end portions in the width direction of the fourth mask 39.

As shown in FIG. 10B, the fifth mask 40 includes a fifth light shielding pattern 45, a sixth light shielding mark 46, the fourth light shielding mark 43, and the fifth light shielding mark 44. Furthermore, the fifth mask 40 includes a protective portion 52.

The fifth light shielding pattern 45 corresponds to the conductive intermediate portion 8 shown in FIG. 5B. The fifth light shielding pattern 45 extends from one end edge to the other end edge in the longitudinal direction of the second mask 30.

The sixth light shielding mark 46 shown in FIG. 10B corresponds to the third conductive mark 21 shown in FIG. 5B. The sixth light shielding mark 46 is disposed in the longitudinal one end portion of the fifth mask 40. The longitudinal one end edge of the sixth light shielding mark 46 is included in the longitudinal one end edge of the fifth mask 40. The sixth light shielding mark 46 extends from the longitudinal one end edge of the fifth mask 40 to the middle in tire longitudinal direction toward the other side. A shape of the sixth light shielding mark 46 is the same as that of the third conductive mark 27.

The fourth light shielding mark 43 and the fifth light shielding mark 44 in the fifth mask 40 have the same configuration (shape, arrangement, etc.) as the fourth light shielding mark 43 and the fifth light shielding mark 44 in the fourth mask 39.

Further, in the fifth mask 40, the sixth light shielding mark 46 is offset with the fourth light shielding mark 43 and the fifth light shielding mark 44 when projected in the longitudinal direction. Specifically, the sixth light shielding mark 46 is located between the fourth light shielding mark 43 and the fifth light shielding mark 44 when projected in the longitudinal direction.

When projected in the longitudinal direction, a width direction distance L3 between the fourth light shielding mark 43 and the sixth light shielding mark 46, and a width direction length L4 between the sixth light shielding mark 46 and the fifth light shielding mark 44 are a length that serves as a reference for measurement of the amount of deviation to be described later. That is, the width direction length L3 and L4 are not dependent on the amount of deviation to be described later. That is, the width direction length L3 and L4 are an inherent amount in the fifth mask 40.

The protective portion 52 is disposed on both sides in the width direction of the sixth light shielding mark 46 in the longitudinal one end portion of the fifth mask 40. Specifically, the two protective portions 52 are a light shielding portion including a pattern obtained by sliding the fourth light shielding mark 43 and the fifth light shielding mark 44 described above on one side in the longitudinal direction (parallel movement).

As shown in FIG. 10C, the sixth mask 41 includes a sixth light shielding pattern 47 and the sixth light shielding mark 46. Furthermore, the sixth mask 41 includes the protective portion 52.

The sixth light shielding pattern 47 corresponds to the conductive other end portion 7 and the conductive intermediate portion 8 shown in FIG 5B. The sixth light shielding pattern 47 extends from the longitudinal one end edge of the sixth mask 41 to the middle in the longitudinal direction toward the other side. The sixth light shielding mark 46 in the sixth mask 41 has the same configuration (shape, arrangement, etc.) as the sixth light shielding mark 46 in the fifth mask 40.

The configuration of the protective portion 52 is the same as that of the protective portion 52 of the fifth mask 40.

In the three masks 30, 40, and 41 described above, each of the light shielding pattern, the light shielding mark, and the protective portion is a light shielding portion for blocking light in the next exposure. In the three masks 39, 40, and 41, a portion other than the light shielding portion is a light transmitting portion that transmits light.

Then, as shown in FIGS. 10A and 11A, in this photolithography, first, the fourth mask 39 is disposed on one side in the thickness direction of the longitudinal one end portion of the photoresist 49. Subsequently, the photoresist 49 is exposed through the fourth mask 39 (first exposure). Then, as shown in FIG. 11A, a latent image 48 corresponding to the fourth light shielding pattern 42, the fourth light shielding mark 43, and the fifth light shielding mark 44 is formed in the photoresist 49. The latent image 48 is an inverted pattern of a portion irradiated by light transmitting through the light transmitting portion other than the light shielding pattern and the light shielding mark in the photoresist 49. A pattern in which light is blocked by the light shielding pattern and the light shielding mark is formed in the photoresist 49.

Then, as shown in FIGS. 10B and 11C, in this photolithography, instead of the fourth mask 39, the fifth mask 40 is disposed on one side in the thickness direction of the photoresist 49. The fifth mask 40 is disposed on the other side in the longitudinal direction with respect to the arrangement portion of the fourth mask 39, and at that time, the longitudinal one end portion of the fourth mask 39 is disposed with respect to the photoresist 49 so as to overlap in the thickness direction with the opposing portion 55 facing the longitudinal other end portion of the fourth mask 39 in the photoresist 49. Subsequently, the photoresist 49 is exposed through the fifth mask 40 (second exposure). Then, the latent image 48 corresponding to the fifth light shielding pattern 45, the fourth light shielding mark 43, the fifth light shielding mark 44, and the sixth light shielding mark 46 is formed.

In the latent image 48, the opposing portion 55 corresponding to the fourth light shielding pattern 42 is overlapped with the portion facing the fifth light shielding pattern 45.

On the other hand, the latent image 48 (ref: FIG. 11A) corresponding to the fourth light shielding mark 43 and the fifth light shielding mark 44 at the time of the first exposure is not overlapped with (is offset with) the latent image 48 (ref: FIG. 11B) corresponding to the sixth light shielding mark 46 at the tune of the second exposure. Specifically, the latent image 48 (ref: FIG. 11A) corresponding to the fourth light shielding mark 43 and the fifth light shielding mark 44 at the time of the first exposure, and the latent image 48 (ref: FIG. 11B) corresponding to the sixth light shielding mark 46 at the time of the second exposure are spaced apart from each other in the width direction. Thus, in the boundary portion 21 between the first sheet area 19A and the second sheet area 19B, the latent image 48 formed using the sixth light shielding mark 46 by the present exposure is added to the latent image 48 formed using the fourth light shielding mark 43 and the fifth light shielding mark 44 by the previous exposure.

The latent image 48 corresponding to the fourth light shielding mark 43, the fifth light shielding mark 44, and the sixth light shielding mark 46 is formed in the photoresist 49.

The protective portion 52 of the fifth mask 40 includes the latent image 48 formed in the photoresist 49 by the fourth light shielding mark 43 and the fifth light shielding mark 44 of the fourth mask 39 at the time of the first exposure. Therefore, light is not irradiated to the latent image 48 described above even by the second exposure through the fifth mask 40. That is, the latent image 48 corresponding to the fourth light shielding mark 43 and the fifth light shielding mark 44 at the time of the first exposure is also protected by the second exposure through the fifth mask 40.

Thereafter, as shown in FIG. 10C, in this photolithography, instead of the fifth mask 40, the sixth mask 41 is disposed on one side in the thickness direction of the photoresist 49. The sixth mask 41 is disposed on the other side in the longitudinal direction with respect to the arrangement portion of the fifth mask 40, and at that time, the longitudinal one end portion of the sixth mask 41 is disposed with respect to the photoresist 49 so as to overlap in the thickness direction with the opposing portion 55 facing the longitudinal other end portion of the fifth mask 40 in the photoresist 49. Subsequently, the photoresist 49 is exposed through die sixth mask 41. Then, the latent image 48 corresponding to the sixth light shielding pattern 47 and the sixth light shielding mark 46 is formed.

In the latent image 48, the opposing portion 55 corresponding to the fifth light shielding pattern 45 is overlapped with the portion facing the sixth light shielding pattern 47.

On the other hand, the latent image 48 corresponding to the fourth light shieling mark 43 and the fifth light shielding mark 44 at the time of the second exposure is not overlapped with (is offset with) the latent image 48 (not shown) corresponding to the sixth light shielding mark 46 at the time of the third exposure. Specifically, the latent image 48 corresponding to the fourth light shieling mark 43 and the fifth light shielding mark 44 at the time of the second exposure, and the latent image 48 corresponding to the sixth light shielding mark 46 at the time of the third exposure are spaced apart from each other in the width direction. Thus, in the boundary portion 21 between the second sheet area 19B and the third sheet area 19C, the latent image 48 formed using the sixth light shielding mark 46 by the present exposure is added to the latent image 48 formed using the fourth light shielding mark 43 and the fifth light shielding mark 44 by the previous exposure.

The protective portion 52 of the sixth mask 41 includes the latent image 48 formed in the photoresist 49 by the fourth light shielding mark 43 and the fifth light shielding mark 44 of the fifth mask 40 at the time of the second exposure. Therefore, light is not irradiated to the latent image 48 described above even by the third exposure through the sixth mask 41. That is, the latent image 48 corresponding to the fourth light shielding mark 43 and the fifth light shielding mark 44 at the time of the second exposure is also protected by the third exposure through the sixth mask 41.

Thereafter, the photoresist 49 in which the latent image 48 described above is formed is developed and heated, if necessary.

Thus, as shown in FIG. 11C, the plating resist 51 of the inverted pattern of the conductive pattern 5, the first conductive mark 25, the second conductive mark 26, and the third conductive mark 27 (ref: FIG. 11D) is formed.

As shown in FIG. 11D, thereafter, the conductive pattern 5, the first conductive mark 25, the second conductive mark 26, and the third conductive mark 27 are formed using the plating resist 51 by plating for supplying electric power to the seed film 50.

Subsequently, as shown in FIG. 3, the plating resist 51 and the seed film 50 located on the other side in the thickness direction thereof are removed.

Thus, the conductive pattern .5 and the conductive measurement mark portion 18 are formed at the same time.

### Fifth Step

Thereafter, the amount of deviation of the masks 39, 40, and 41 shown in FIGS. 10A to 10C is measured.

FIG. 13A shows an embodiment in which in the boundary portion 21 between the first sheet area 19A and the second sheet area 19B, the fourth light shielding pattern 42 of the fourth mask 39, and the fifth light shielding pattern 45 of the fifth mask 40 deviate. Further, FIG. 13B shows the conductive pattern 5 and the conductive measurement mark portion 18 formed by the fourth mask 39 and the fifth mask 40 described above.

As shown in FIG. 13B, first, in the fifth step, the conductive measurement mark portion 18 in the boundary portion 21 between the first sheet area 19A and the second sheet area 19B is detected. Specifically, as shown in FIG. 4, since the conductive measurement mark portion 18 is located in the insulating measurement mark portion 17, when the insulating measurement mark portion 17 is detected, the conductive measurement mark portion 18 can be easily detected.

Subsequently, a width direction distance L13 between the first conductive mark 25 and the third conductive mark 27 in the conductive measurement mark portion 18 is measured. Then, the distance L13 is compared with the width direction distance L3 (ref: FIG. 10B) between the fourth light shielding mark 43 and the sixth light shielding mark 46. As shown in FIG. 13A, a difference between the distance L13 and the width direction distance L3 is obtained as a width direction deviation of the longitudinal other end portion of the fourth light shielding pattern 42 of the fourth mask 39 with the longitudinal one end portion of the fifth light shielding pattern 45 of the fifth mask 40. As shown in FIG. 13B, this deviation corresponds to a deviation between the end edge in the width direction of the conductive intermediate portion 8 of the first sheet area 19A and the end edge m the width direction of the conductive intermediate portion 8 of the second sheet area 19B in the opposing portion 55 of the photoresist 49.

At the same time, a width direction distance L14 between the third conductive mark 27 and the second conductive mark 26 is measured. Then, the distance L14 is compared with the width direction length L4 (ref: FIG. 10B) between the sixth light shielding mark 46 and the fifth light shielding mark 44. As shown in FIG. 13A, a difference between the distance L14 and the width direction length L4 is obtained as a width direction deviation of the longitudinal other end portion of the fourth light shielding pattern 42 of the fourth mask 39 with the longitudinal one end portion of the fifth light shielding pattern 45 of the fifth mask 40. As shown in FIG. 13B, this deviation corresponds to a deviation between the end edge in the width direction of the conductive intermediate portion 8 of the first sheet area 19A and the end edge in the width direction of the conductive intermediate portion 8 of the second sheet area 19B.

The measurement described above is carried out in the conductive measurement mark portion 18 in both end portions in the width direction, and also earned out in the conductive measurement mark portion 18 of the boundary portion 21 between the second sheet area 19B and the third sheet area 19C.

Thereafter, the position in the width direction of the masks 39, 40, and 41 with respect to the photoresist 49 in which the formation of the conductive pattern 5 is scheduled next is adjusted based on the deviation of the masks 39, 40, and 41.

When the deviation of the conductive intermediate portion 8 described above is within the range of tolerances, the following sixth step is carried out. On the other hand, when the deviation of the conductive intermediate portion 8 is outside the range of tolerances, the following sixth step is not carried out and excluded from a production target (production line). That is, when the wiring circuit board sheet 1 is a defective component, the following sixth step is not carried out and excluded from the production target (production line). Thus, it is possible to direct a material for the cover insulating layer 10 in the sixth step to the production of a non-defective cover insulating layer 10.

### Sixth Step

As shown in FIGS. 2 and 5C, the cover insulating layer 10 is formed on one surface in the thickness direction of the base insulating layer 9 so as to cover a wire of the conductive pattern 5.

Thus, the wiring circuit board sheet 1 including the support sheet 2, the wiring circuit board 3, and the plurality of measurement mark portions 4 is obtained

### Function and Effect of One Embodiment

Then, in this method, as shown in FIG 4, the distance L13 between the first conductive mark 25 and the third conductive mark 27 is measured, and the distance L13 is compared with the distance L3 (FIG. 10B) between the fourth light shielding mark 43 and the sixth light shielding mark 46 in the projected surface when projected in the longitudinal direction.

By determining the difference between the distance L13 and the distance L1, it is possible to measure the amount of deviation between the longitudinal other end portion of the fourth mask 39 and the longitudinal one end portion of the fifth mask 40.

Therefore, thereafter, it is possible to adjust the arrangement of the masks 39, 40, and 41 when the same fourth step is carried out.

Furthermore, the amount of deviation between the longitudinal other end portion of the conductive intermediate portion 8 corresponding to the fourth light shielding pattern 42 of the fourth mask 39 and the longitudinal one end portion of the conductive intermediate portion 8 corresponding to the fourth light shielding pattern 42 of the fifth mask 40 can be accurately measured. The amount of deviation between the longitudinal other end portion of the conductive intermediate portion 8 corresponding to the fourth light shielding pattern 42 of the fifth mask 40 and the longitudinal one end portion of the conductive intermediate portion 8 corresponding to the fourth light shielding pattern 42 of the sixth mask 41 can be also accurately measured in the same manner as described above.

In this method, by measuring both the distance L13 between the first conductive mark 25 and the third conductive mark 27, and the width direction distance L12 between the third insulating mark 24 and the second insulating mark 23, the amount of deviation between the longitudinal other end portion of the fourth mask 39 and the longitudinal one end portion of the fifth mask 40 can be accurately measured. Therefore, the amount of deviation between the longitudinal other end portion of the conductive intermediate portion 8 corresponding to the fifth light shielding pattern 45 of the fourth mask 39 and the longitudinal one end portion of the conductive intermediate portion 8 corresponding to the fifth light shielding pattern 45 of the fifth mask 40 can be more accurately measured. The amount of deviation between the longitudinal other end portion of the conductive intermediate portion 8 corresponding to the fourth light shielding pattern 42 of the fifth mask 40 and the longitudinal one end portion of the conductive intermediate portion 8 corresponding to the fourth light shielding pattern 42 of the sixth mask 41 can be also more accurately measured in the same manner as described above. Therefore, it is possible to accurately determine the defectiveness of the conductive pattern 5.

Furthermore, in this method, in one boundary portion 21, the plurality of (two) conductive measurement mark portions 18 are spaced apart from each other in the width direction, so that, for example, by comparing the distance L13 of the conductive measurement mark portion 18 on one side in the width direction with the distance L13 of the conductive measurement mark portion 18 on the other side in the width direction, the rotation and the amount of rotation of the fifth mask 40 with respect to the position obtained by parallel movement (sliding) of the fourth mask 39 toward the other side in the longitudinal direction can be measured.

Further, in this method, the distance L11 between the first insulating mark 22 and the third insulating mark 24 is measured, and the distance L11 is compared with the distance L1 between the first light transmitting mark 33 and the third light transmitting mark 36 in the projected surface when projected in the longitudinal direction. By determining the difference between the distance L11 and the distance L1, the amount of deviation between the longitudinal other end portion of the first mask 29 and the longitudinal one end portion of the second mask 30 can be measured.

Therefore, it is possible to adjust the arrangement of the masks 29, 30, and 31 when the same second step is carried out.

Furthermore, the amount of deviation between the longitudinal other end portion of the base intermediate portion 13 corresponding to tire first light transmitting pattern 32 of the first mask 29 and the longitudinal one end portion of the base intermediate portion 13 corresponding to the first light transmitting pattern 32 of the second mask 30 can be accurately measured. The amount of deviation between the longitudinal other end portion of the base intermediate portion 13 corresponding to the second light transmitting pattern 35 of the second mask 30 and the longitudinal one end portion of the base intermediate portion 13 corresponding to the third light transmitting pattern 37 of the third mask 31 can be also accurately measured.

Since the wiring circuit board 3 includes the conductive measurement mark portion 18, it is possible to measure the amount of deviation of the conductive intermediate portion 8 of the conductive pattern 5 and accurately determine the defectiveness of the conductive pattern 5. Therefore, in the wiring circuit board sheet 1, the conductive pattern 5 is excellent in reliability.

Since the wiring circuit board 3 includes the insulating measurement mark portion 17, it is possible to measure the amount of deviation of the base intermediate portion 13 of the base insulating layer 9 and accurately determine the defectiveness of the base insulating layer 9. Therefore, in the wiring circuit board sheet 1, the base insulating layer 9 is excellent in reliability.

Furthermore, in the wiring circuit board 3, since the conductive measurement mark portion 18 is overlapped with the insulating measurement mark portion 17, the configuration of the measurement mark portion 4 becomes compact. Further, of the insulating measurement mark portion 17 and the conductive measurement mark portion 18, when one is detected, the other can be easily detected.

### Modified Examples

Next, modified examples of one embodiment are described in the following modified examples, the same reference numerals are provided for members and steps corresponding to each of those in the above-described one embodiment, and their detailed description is omitted. One embodiment and each of the modified examples can be appropriately used in combination. Furthermore, the modified examples can achieve the same function and effect as that of the above-described one embodiment unless otherwise specified.

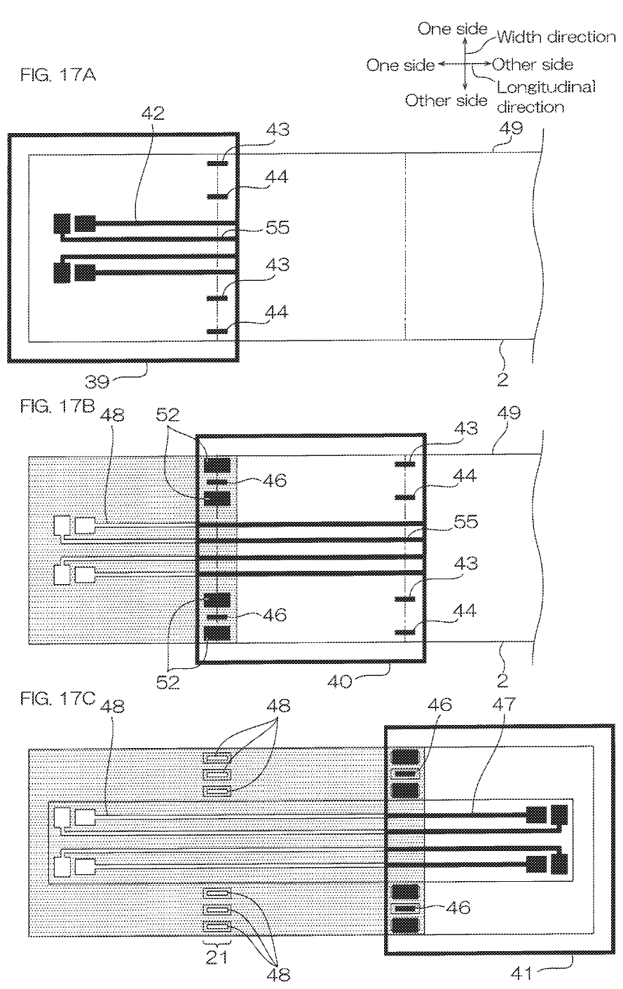

In FIGS. 17A to 22C, in order to clearly show the arrangement and shape of the conductive measurement mark portion 18, the insulating measurement mark portion 17 and the base insulating layer 9 are omitted.

In one embodiment, the third step is carried out before the fourth step. Alternatively, the third step can be also carried out after the fourth step. For example, the third step is carried out after the fourth step and simultaneously with the fifth step.

Or, for example, the third step and the fifth step can be also carried out simultaneously after the sixth step.

In one embodiment, the first conductive mark 25 and the second conductive mark 26 are formed and thereafter, the third conductive mark 27 is formed. They may be formed in the reversed order.

In this modified example, though not shown, the measurement mark portion 4 includes a cover insulating measurement mark that is the same layer as the cover insulating layer 10.

Further, the insulating measurement mark portion 17 and the conductive measurement mark portion 18 may deviate from each other when viewed from the top. Preferably, the insulating measurement mark portion 17 is overlapped with the conductive measurement mark portion 18. By this configuration, the configuration of the measurement mark portion 4 becomes compact. Further, of the insulating measurement mark portion 17 and the conductive measurement mark portion 18, when one is detected, the other can be easily detected.

In the modified example, the measurement mark portion 4 includes only one of the insulating measurement mark portion 17 and the conductive measurement mark portion 18.

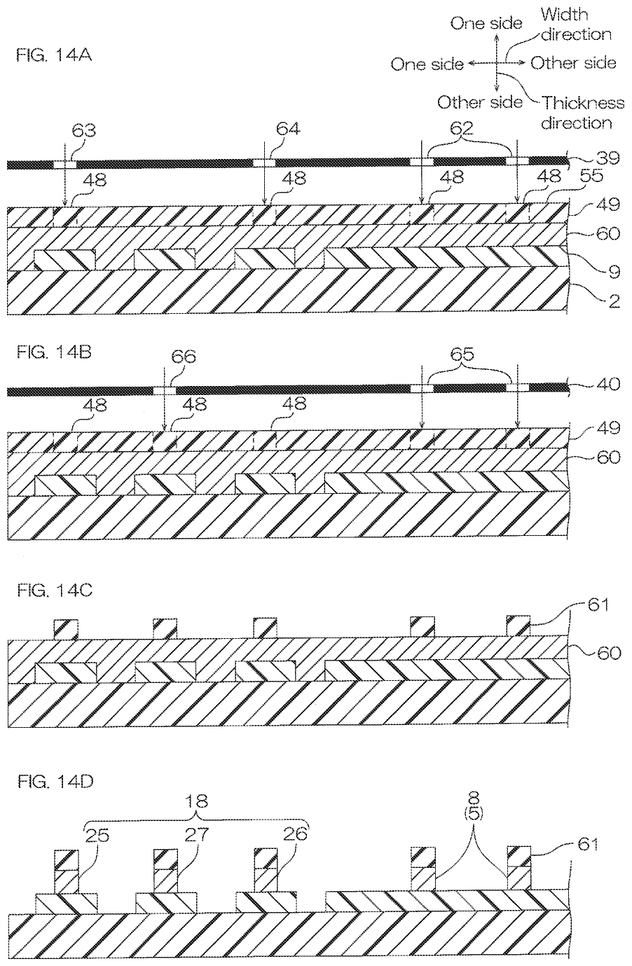

In one embodiment, the conductive pattern 5 and the conductive measurement mark portion 18 are formed by plating. On the other hand, in the modified example, as shown in FIGS. 14A to 14D, the conductive pattern 5 and the conductive measurement mark portion 18 are formed by etching. In the modified example, for example, an etching resist 61 is formed from the photoresist 49. and a conductive sheet 60 is etched using the etching resist 61.

Specifically, first, as shown in FIG. 14A, the conductive sheet 60 is attached to the surfaces of the support sheet 2, the base insulating layer 9, and the insulating measurement mark portion 17 through an adhesive that is not shown. Subsequently, the photoresist 49 is laminated on one surface in the thickness direction of the conductive sheet 60.

The photoresist 49 is exposed a plurality of times while the masks 39, 40, and 41 are sequentially arranged. In the masks 39, 40, and 41, the light shielding patterns 42, 45, 47, and the light shielding marks 43, 44, 46 shown in FIGS. 10A to 11B turn to be light transmitting patterns 62, 65, 67 and light transmitting marks 63, 64, 67. The masks 39, 40, and 41 do not include a protective portion.

Each of the light transmitting patterns 62, 65, and 67 and each of the light transmitting marks 63, 64, and 66 have the same shape and arrangement as each of the light shielding patterns 42, 45, and 47 and each of the light shielding marks 43, 44, and 46 of one embodiment. The fourth mask 39 includes the fourth light transmitting pattern 62, the fourth light transmitting mark 63, and the fifth light transmitting mark 64. The fifth mask 40 includes the fifth light transmitting pattern 65 and the sixth light transmitting mark 66. The sixth mask 41 includes the sixth light transmitting pattern 67 and the sixth light transmitting mark 66.

In the first exposure using the fourth mask 39, the latent image 48 by irradiation of light transmitting through the fourth light transmitting pattern 62, the fourth light transmitting mark 63, and the fifth light transmitting mark 64 is formed in the photoresist 49.

In the second exposure using the fifth mask 40, the latent image 48 by irradiation of light transmitting through the sixth light transmitting pattern 65 is newly formed in the photoresist 49.

As shown in FIG. 14C, the photoresist 49 is developed to form the etching resist 61.

Thereafter, as shown in FIG. 14D, by etching the conductive sheet 60 exposed from the etching resist 61, the conductive measurement mark portion 18 and the conductive pattern 5 are formed.

Thereafter, as shown in FIG. 7B, the etching resist 61 is removed.

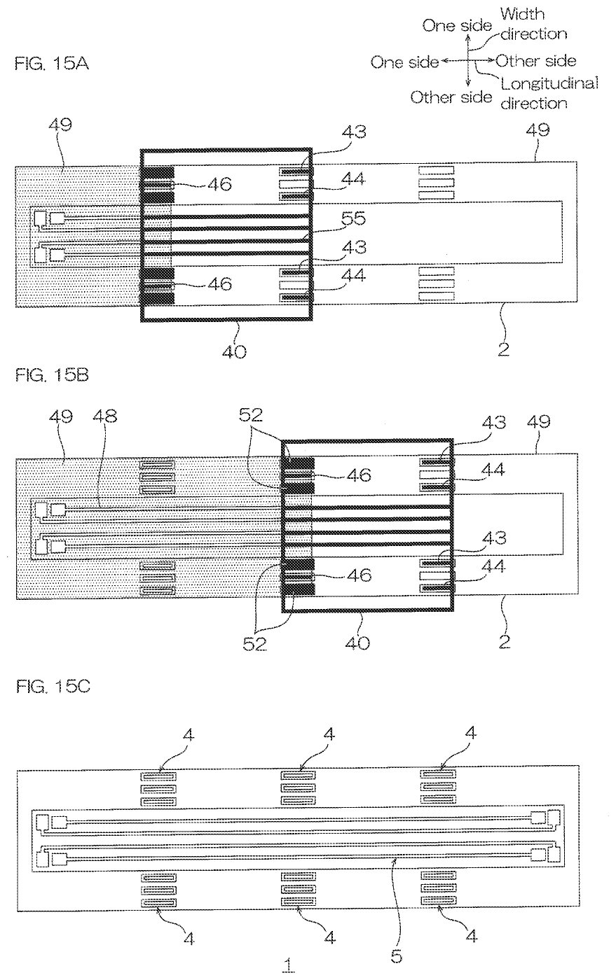

Further, in the modified example, as shown in FIGS. 15A to 15C, the photoresist 49 is exposed a plurality of times while the same mask is sequentially arranged in the longitudinal direction. That is, the photoresist 49 is exposed a plurality of times while the same mask used only for the formation of the conductive intermediate portion 8, that is, other than the mask used for the formation of the conductive one end portion 6 and the conductive other end portion 7 of the conductive pattern 5 is sequentially arranged in the longitudinal direction.

Specifically, after the second exposure (ref: FIG. 15A), as shown in FIG. 15B, the fifth mask 40 used in the second exposure is slid (moved) toward the other side in the longitudinal direction. At this time, the sliding fifth mask 40 is overlapped with the opposing portion 55 described above in the photoresist 49.

In this modified example, the photoresist 49 is exposed four times through the mask, and in each of both end portions in the width direction of the wiring circuit board sheet 1, the three measurement mark portions 4 are formed.

Although not shown, the photoresist 49 is exposed twice through the fifth mask 40, and in each of both end portions in the width direction of the wiring circuit board sheet 1, the one measurement mark portion 4 can be formed. The number of exposures may be five times or more.

That is, the number of exposures is referred to as “n+1” (n is a natural number), and the number of measurement mark portions 4 in each of both end portions in the width direction of the wiring circuit board sheet 1 is referred to as “n” (n is a natural number).

Further, though not shown, the measurement mark portion 4 can be formed only in one end portion in the width direction of the support sheet 2.

Preferably, the measurement mark portion 4 is formed in both end portions in the width direction of the support sheet 2. This allows the rotation of the mask and its amount to be measured.

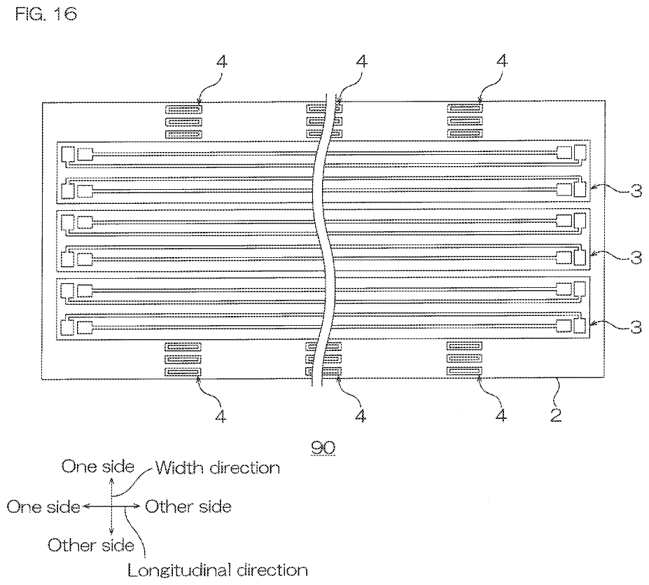

As shown in FIG. 16, a wiring circuit board assembly sheet 90 in which the plurality of wiring circuit boards 3 are supported by the one support sheet 2 may be used instead of the wiring circuit board sheet 1. The plurality of wiring circuit boards 3 are arranged to be adjacent to each other at a distance in the width direction.

The arrangement of the measurement mark portion 4 is not limited to the end portion in the width direction of the support sheet 2. Although not shown, for example, the arrangement of the measurement mark portion 4 may be the central portion in the width direction. Although not shown, for example, the arrangement of the measurement mark portion 4 may be between the wiring circuit boards 3 adjacent to each other in the width direction.

As shown in FIGS. 17A to 17C, the fourth light shielding mark 43, the fifth light shielding mark 44, and the sixth light shielding mark 46 are spaced apart from both end edges in the longitudinal direction of the masks 39, 40, and 41.

Specifically, the fourth light shielding mark 43 and the fifth light shielding mark 44 are spaced apart front the longitudinal other end edge in each of the fourth mask 39 and the fifth mask 40.

The sixth light shielding mark 46 is spaced apart front the longitudinal one end edge in each of the fifth mask 40 and the sixth mask 41.

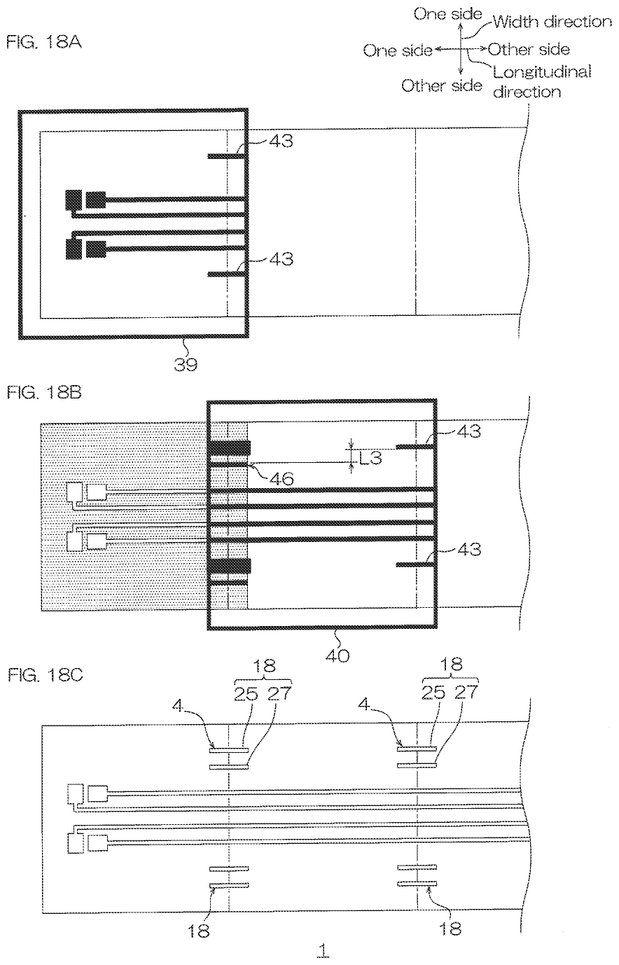

As shown in FIG 18C, the conductive measurement mark portion 18 (one example of a first measurement mark portion) does not include the second conductive mark 26 (one example of the other portion, ref: FIG. 4), and can also include only the first conductive mark 25 (one example of one portion).

Each of the fourth mask 39 and the fifth mask 40 does not include the fifth light shielding mark 44 (ref: FIGS. 10A to 10B), and includes the fourth light shielding mark 43.

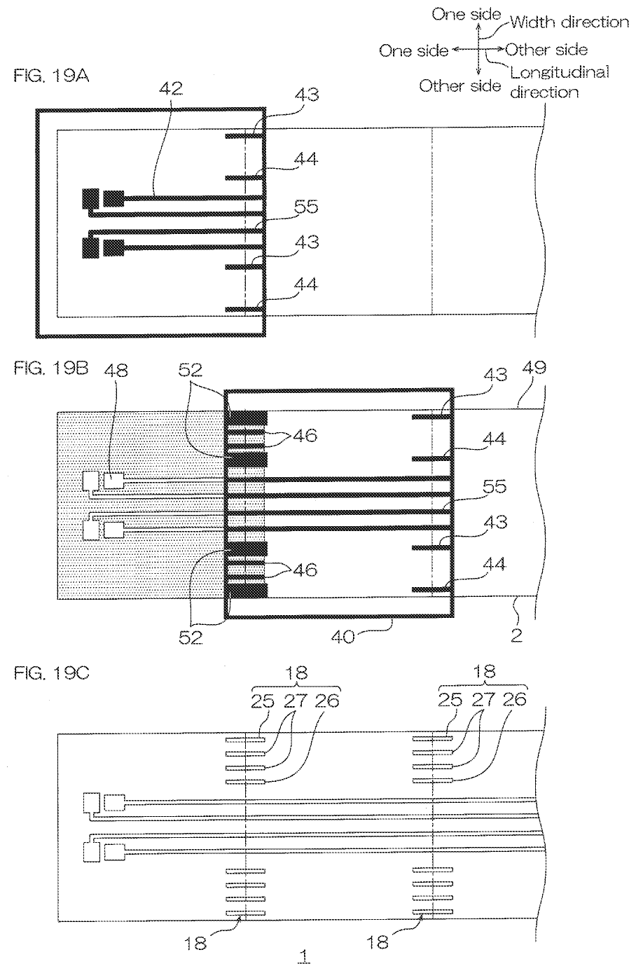

As shown in FIGS. 19A to 19B, the number of the sixth light shielding mark 46 may be two. The two sixth light shielding marks 46 are arranged to be adjacent to each other at a distance in the width direction.

As shown in FIG. 19C, the conductive measurement mark portion 18 includes the two third conductive marks 27 corresponding to the two sixth light shielding marks 46.

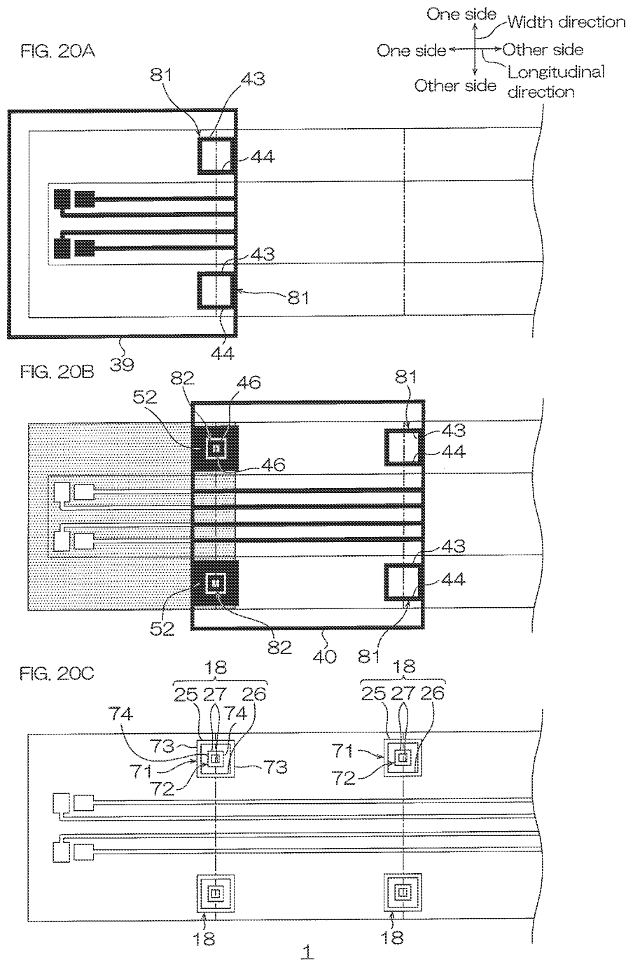

As shown in FIG. 20C, the conductive measurement mark portion 18 has a double rectangular frame shape when viewed from the top. The conductive measurement mark portion 18 includes a first portion 71 and a second portion 72.

The first portion 71 has a rectangular frame shape when viewed from the top. The first portion 71 includes the first conductive mark 25, the second conductive mark 26, and two first connecting pieces 73 connecting both end edges in the longitudinal direction of these.

The second portion 72 is disposed at the inside of the first portion 71 so as to be surrounded by the first portion 71. The second portion 72 has a rectangular frame shape when viewed from the top. The second portion 72 includes the two third conductive marks 27, and two second connecting pieces 74 connecting both end edges in the longitudinal direction of these.

As shown in FIGS. 20A to 20B, the fourth mask 39 and the fifth mask 40 include one light shielding mark 81 corresponding to the first portion 71 find including the fourth light shielding mark 43 and the fifth light shielding mark 44 (ref: FIGS. 10A to 10B) in the longitudinal other end portion.

The fifth mask 40 includes another light shielding mark 82 corresponding to the second portion 72 and including the two sixth light shielding marks 46 in the longitudinal one end portion.

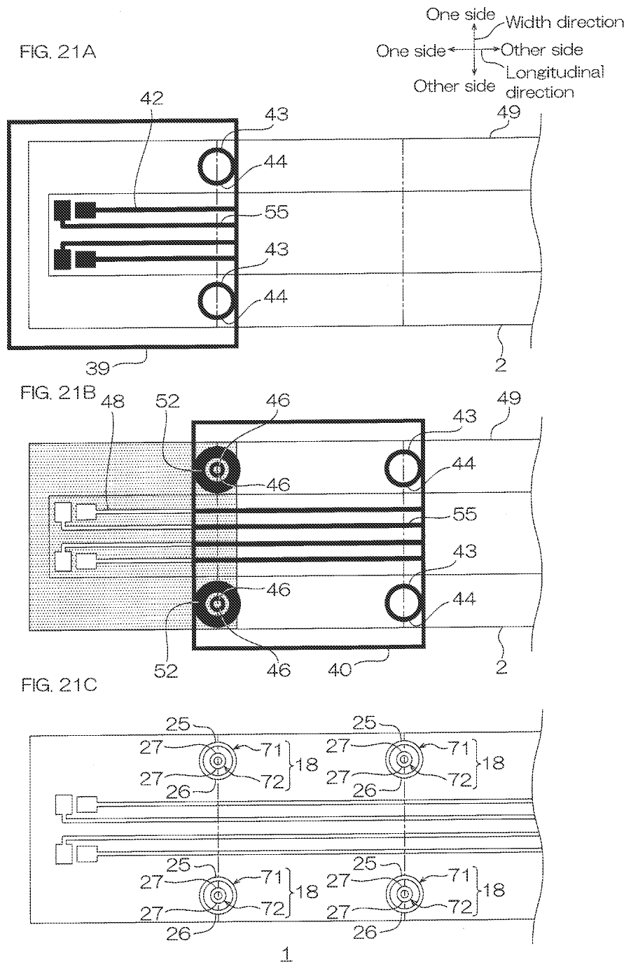

As shown in FIG. 21C, the conductive measurement mark portion 18 has a double circular ring shape when viewed from the top. The conductive measurement mark portion 18 includes the first portion 71 and the second portion 72.

The first portion 71 has a circular ring shape when viewed from the top. The first portion 71 integrally includes the first conductive mark 25 in a semicircular arc shape when viewed from the top and the second conductive mark 26 in a semicircular arc shape when viewed from the top.

The second portion 72 includes one third conductive mark 27 in a semicircular arc shape when viewed from the top and another third conductive mark 27 in a semicircular arc shape when viewed from the top.

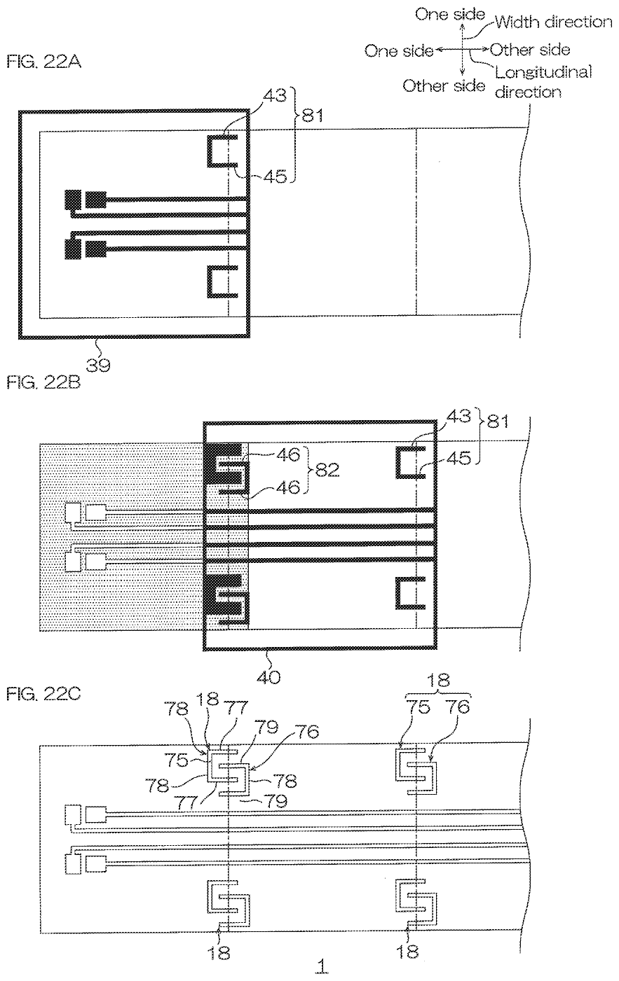

As shown in FIG. 22C, the conductive measurement mark portion 18 includes a first U-shaped portion (first square U-shaped portion) 75, and a second U-shaped portion (second square U-shaped portion) 76 so as to deviate in the width direction.

The first U-shaped portion 75 has a shape that opens toward the other side in the longitudinal direction. The first U-shaped portion 75 integrally includes two first opposing pieces 77 as one example of a first conductive mark, and a first connecting piece 78. The two first opposing pieces 77 are spaced apart from each other in the width direction, each extending in the longitudinal direction. The first connecting piece 78 connects the longitudinal one end edges of the two first opposing pieces 77.

The second U-shaped portion 76 has a shape that opens toward one side in the longitudinal direction. The second U-shaped portion 76 integrally includes two second opposing pieces 70 as one example of a second conductive mark, and a second connecting piece 80. The two second opposing pieces 79 are spaced apart from each other in the width direction, each extending in the longitudinal direction. The second connecting piece 80 connects the longitudinal other end edges of the two second opposing pieces 79.

As shown in FIGS. 22A to 22B, the fourth mask 39 and the fifth mask 40 include one light shielding mark 81 corresponding to the first U-shaped portion 75 and including the fourth light shielding mark 43 and the fifth light shielding mark 44 in the longitudinal other end portion.

The fifth mask 40 includes another light shielding mark 82 corresponding to the second U-shaped portion 76 and including the two sixth light shielding marks 46 in the longitudinal one end portion.

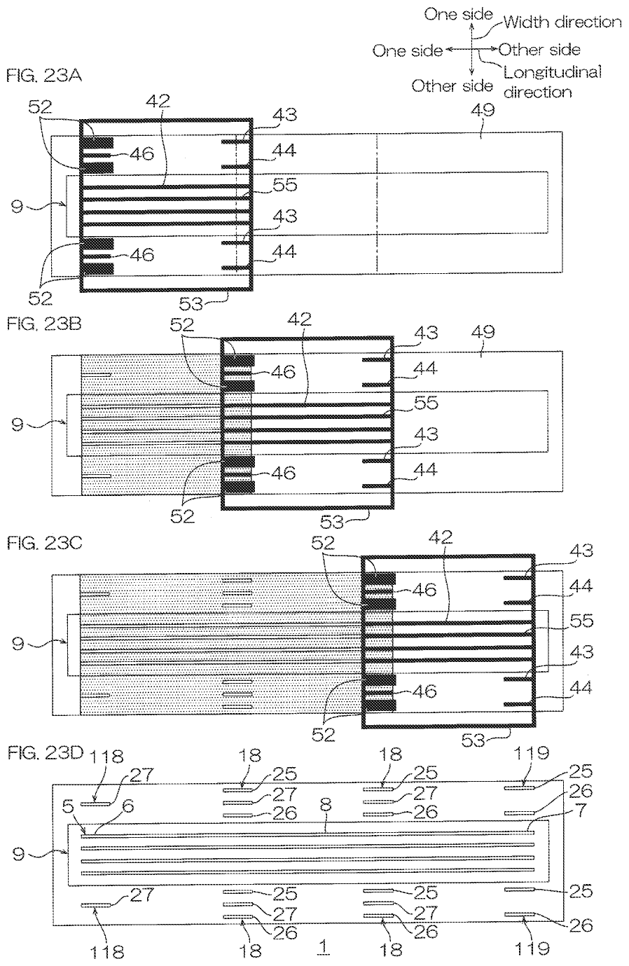

In FIGS. 15A to 15C, the mask forming the conductive one end portion 6 and the mask forming the conductive other end portion 7 are different from the mask forming the conductive intermediate portion 8. Alternatively, for example, as shown in FIGS. 23A to 23C, they may be all the same mask.

A mask 53 used in the exposure in the fourth step includes the fourth light shielding pattern 42. The fourth light shielding pattern 42 extends from one end edge to the other end edge in the longitudinal direction of the mask 53. A width of the fourth light shielding pattern 42 is the same over the longitudinal direction. The fourth light shielding pattern 42 has a generally linear shape when viewed from the top.

As shown in FIG. 23A, the mask 53 is disposed on one side in the thickness direction of die longitudinal one end portion of the photoresist 49, and subsequently, the photoresist 49 is exposed through the mask 53 (first exposure).

As shown in FIG. 23B, then, the mask 53 used in the first exposure is slid (moved) toward the other side in the longitudinal direction, and subsequently, the photoresist 49 is exposed through the mask 53 (second exposure).

As shown in FIG. 23C, thereafter, the mask 53 used in the second exposure is further slid (moved) toward the other side in the longitudinal direction, and subsequently, the photoresist 49 is exposed through the mask 53 (third exposure).

That is, in the fourth step, the same mask 53 is used in all exposures.

As shown in FIG 23D, thus, the plurality of linear conductive patterns 5 extending along the longitudinal direction are formed.

The longitudinal one end portion of the conductive pattern 5 is referred to as a one-side terminal of the same width as the conductive intermediate portion 8. A first mark portion 118 disposed on both sides in the width direction of the one-side terminal includes the third conductive mark 27, and does not include the first conductive mark 25 and the second conductive mark 26. Therefore, the first mark portion 118 is not used for measuring the deviation of the mask 53 during the sliding of the mask 53.

The longitudinal other end portion of the conductive pattern 5 is referred to as the other-side terminal of the same width as the conductive intermediate portion 8. A second mark portion 119 disposed on both sides in the width direction of the other-side terminal includes the first conductive mark 25 and the second conductive mark 26, and does not include the third conductive mark 27. Therefore, the second mark portion 119 is not used for measuring the deviation of the mask 53 during the sliding of the mask 53

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### DESCRIPTION OF SYMBOLS

1 Wiring circuit board sheet
2 Support sheet
3 Wiring circuit board
4 Measurement mark portion
5 Conductive pattern
6 Conductive one end portion
7 Conductive other end portion
8 Conductive intermediate portion
9 Base insulating layer
10 Cover insulating layer
11 Base one end portion
12 Base other end portion
13 Base intermediate portion
17 Insulating measurement mark portion
18 Conductive measurement mark portion
19 Sheet area
21 Boundary portion
22 First insulating mark
23 Second insulating mark
24 Third insulating mark
25 First conductive mark
26 Second conductive mark
27 Thud conductive mark
28 Photosensitive base precursor layer
29 First mask
30 Second mask
31 Third mask
32 First light transmitting pattern
33 First light transmitting mark
34 Second light transmitting mark
35 Second light transmitting pattern
36 Third light transmitting mark
37 Third light transmitting pattern
39 Fourth mask
40 Fifth mask
41 Sixth mask
42 Fourth light shielding pattern
43 Fourth light shielding mark
44 Fifth light shielding mark
45 Fifth light shielding pattern
46 Sixth light shielding mark
47 Sixth light shielding pattern
49 Photoresist
53 Mask
55 Opposing portion
62 Fourth light transmitting pattern
63 Fourth light transmitting mark
64 Fifth light transmitting mark
65 Sixth light transmitting pattern
66 Fifth light shielding pattern
77 First opposing piece
79 Second opposing piece
90 Wiring circuit board assembly sheet

1. A method for producing a wiring circuit board comprising the steps of:
forming an elongated insulating layer, and
forming a conductive layer elongated along the insulating layer and adjacent to the insulating layer in a thickness direction perpendicular to a longitudinal direction, wherein
the conductive layer has an intermediate portion located between one end portion and the other end portion in the longitudinal direction,
in the step of forming the conductive layer,
an elongated photoresist is placed along the insulating layer on one side in the thickness direction of the insulating layer, the photoresist is exposed a plurality of times while a mask is sequentially arranged in the longitudinal direction, the photoresist is developed after exposure, a resist corresponding to the conductive layer is formed, and plating or etching is carried out using the resist,
the mask has at least a pattern corresponding to the intermediate portion of the conductive layer,
in the step of exposing the photoresist, in the photoresist, a portion facing the longitudinal other end portion of the mask at the lime of the n-th time (n is a natural number) exposure is overlapped with a portion facing the longitudinal one end portion of the mask at the time of the [n+1]th time exposure,
the longitudinal other end portion of the n-th time mask includes the pattern and a first mark,
the longitudinal one end portion of the [n+1]th time mask includes the pattern and a second mark, and
in the step of forming the conductive layer,
one conductive mark portion is formed by the n-th time exposure of the photoresist through the first mark, formation of the resist by development of the photoresist after exposure, and plating or etching using the resist and
another conductive mark portion adjacent to the one conductive mark portion when projected in the longitudinal direction is formed by the [n+1]th time exposure of the photoresist through the second mark, formation of the resist by development of the photoresist after exposure, and plating or etching using the resist.

2. The method for producing a wiring circuit board according to claim 1, wherein
one of the one conductive mark portion and the other conductive mark portion includes one portion and the other portion which are arranged to be opposed to each other at a distance in a direction perpendicular to the longitudinal direction and the thickness direction, and
the other includes a middle portion which is arranged between one portion and the other portion and is separated from one portion and the other portion.

3. The method for producing a wiring circuit board according to claim 1, wherein
a plurality of measurement mark portions including the one conductive mark portion and the other conductive mark portion are arranged at intervals from each other in a direction perpendicular to the longitudinal direction and the thickness direction.

4. The method for producing a wiring circuit board according to claim 2, wherein
a plurality of measurement mark portions including the one conductive mark portion and the other conductive mark portion are arranged at intervals from each other in a direction perpendicular to the longitudinal direction and the thickness direction.

5. A method for producing a wiring circuit board comprising the steps of:
forming an elongated insulating layer, and
forming a conductive layer elongated along the insulating layer and adjacent to the insulating layer in a thickness direction perpendicular to a longitudinal direction, wherein
the insulating layer has an intermediate portion located between one end portion and the other end portion in the longitudinal direction,
in the step of forming the insulating layer,
an elongated photosensitive resin insulating layer is placed, the photosensitive resin insulating layer is exposed a plurality of times while a mask is sequentially arranged in the longitudinal direction, and the photosensitive resin insulating layer is developed after exposure,
the mask has at least a pattern corresponding to the intermediate portion of the insulating layer,
in the step of exposing the photosensitive resin insulating layer, in the photosensitive resin insulating layer, a portion facing the longitudinal other end portion of the mask at the time of the n-th time (n is a natural number) exposure is overlapped with a portion facing the longitudinal one end portion of the mask at the time of the [n+1]th time exposure,
the longitudinal other end portion of the n-th time mask includes the pattern and a third mark.
the longitudinal one end portion of the [n+1]th time mask includes the pattern and a fourth mark, and
in the step of forming the insulating layer,
one insulating mark portion is formed by the n-th time exposure of the photosensitive resin insulating layer through the third mark and development of the photosensitive resin insulating layer after exposure and
another insulating mark portion adjacent to the one insulating mark portion when projected in the longitudinal direction is formed by the [n+1]th time exposure of the photosensitive resin insulating layer through the fourth mark and development of the photosensitive resin insulating layer after exposure.

6. A wiring circuit board sheet comprising:
an elongated support sheet,
a base insulating layer extending in a longitudinal direction of the support sheet and disposed on one surface in a thickness direction of the support sheet,
a conductive layer extending in the longitudinal direction and disposed on one surface in the thickness direction of the base insulating layer, and
a plurality of areas partitioned in order in the longitudinal direction, wherein
the conductive layer has an intermediate portion located between one end portion and the other end portion in the longitudinal direction, and
a first measurement mark portion disposed at a boundary portion of the areas adjacent to each other in the longitudinal direction, configured to measure an amount of deviation of the intermediate portion at the boundary portion in a direction perpendicular to the thickness direction and the longitudinal direction, and independent from the conductive layer is included.

7. The wiring circuit board sheet according to claim 6, wherein
the base insulating layer has a second intermediate portion located between one end portion and the other end portion in the longitudinal direction, and
a second measurement mark portion configured to measure an amount of deviation of the second intermediate portion at the boundary portion in the perpendicular direction and independent from the base insulating layer is included.

8. The wiring circuit board sheet according to claim 7, wherein
the first measurement mark portion and the second measurement mark portion overlap.
